(19) United States
(12) Patent Application Publication
(10) Pub. No.: US 2025/0364492 A1
(43) Pub. Date: Nov. 27, 2025

(54) IN TIER MULTIPLEXER

(71) Applicant: Micron Technology, Inc., Boise, ID (US)

(72) Inventors: Kamal M. Karda, Boise, ID (US); David A. Daycock, Boise, ID (US); Ting Zhao, Boise, ID (US); Albert Liao, Boise, ID (US); Durai Vishak Nirmal Ramaswamy, Boise, ID (US); Si-Woo Lee, Saratoga, CA (US)

(21) Appl. No.: 19/214,382

(22) Filed: May 21, 2025

Related U.S. Application Data
(60) Provisional application No. 63/650,493, filed on May 22, 2024.

(51) Int. Cl. H01L 25/065; H01L 21/762; H10B 12/00; H10B 80/00

(52) U.S. Cl. CPC H01L 25/0657; H01L 21/76224; H10B 12/053; H10B 12/09; H10B 12/482; H10B 12/485; H10B 12/50; H10B 80/00

(57) ABSTRACT

Systems, methods, and apparatus are provided for forming in tier multiplexers in vertical three dimensional (3D) memory. An array of vertically stacked memory cells can include a first isolation region in a storage node region of an array of vertically stacked memory cells, wherein the isolation region is in an uppermost layer of the array of vertically stacked memory cells, and a multiplexer device in a storage node region of the array of vertically stacked memory cells, wherein the multiplexer device is horizontally adjacent to the first isolation region. A digit line contact can be coupled to a first source/drain region of the multiplexer device, and a first digit line can be coupled to a second source/drain region of the multiplexer device.

### PRIORITY INFORMATION

This application claims the benefit of U.S. Provisional Application No. 63/650,493, filed on May 22, 2024, the contents of which are incorporated herein by reference.

### TECHNICAL FIELD

The present disclosure relates generally to memory devices, and more particularly, to in tier multiplexers in vertical three dimensional (3D) memory.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain regions separated by epitaxially grown channel regions. A gate may oppose the channel region and be separated therefrom by a gate dielectric. An access line, such as a word line, is electrically connected to the gate of the DRAM cell. A DRAM cell can include a storage node, such as a capacitor cell, coupled by the access device to a digit line. The access device can be activated (e.g., to select the cell) by an access line coupled to the access transistor. The capacitor can store a charge corresponding to a data value of a respective cell (e.g., a logic “1” or “0”).

### BRIEF DESCRIPTION OF THE DRAWINGS

FIG. 1A is a schematic illustration of a horizontal access device in a vertical three-dimensional (3D) memory in accordance with a number of embodiments of the present disclosure.

FIG. 1B is a perspective view illustrating a portion of a horizontal access device in vertical three-dimensional (3D) memory in accordance with a number of embodiments of the present disclosure.

FIG. 2 illustrates a portion of a horizontal access device in vertical three-dimensional (3D) memory in accordance with a number of embodiments of the present disclosure.

FIG. 3 illustrates a portion of a vertical 3D memory array in accordance with a number of embodiments of the present disclosure.

FIGS. 4A to 4B illustrate a cross-sectional view, at one stage of a semiconductor fabrication process, for forming vertical three-dimensional (3D) memory in accordance with a number of embodiments of the present disclosure.

FIGS. 5A to 5B illustrate an example method, at one stage of a semiconductor fabrication process, for forming vertical three-dimensional (3D) memory in accordance with a number of embodiments of the present disclosure.

FIGS. 6A to 6D illustrate an example method, at another stage of a semiconductor fabrication process, for forming vertical three-dimensional (3D) memory in accordance with a number of embodiments of the present disclosure.

FIGS. 7A to 7B illustrate an example method, at another stage of a semiconductor fabrication process, for forming vertical three-dimensional (3D) memory in accordance with a number of embodiments of the present disclosure.

FIG. 8 illustrates an example method, at another stage of a semiconductor fabrication process, for forming vertical three-dimensional (3D) memory in accordance with a number of embodiments of the present disclosure.

FIGS. 9A to 9C illustrate an example method, at another stage of a semiconductor fabrication process, for forming vertical three-dimensional (3D) memory in accordance with a number of embodiments of the present disclosure.

FIGS. 10A to 10E are block diagrams of multiplexer devices in an array of vertically stacked memory cells in vertical three-dimensional (3D) memory in accordance with a number of embodiments of the present disclosure.

FIG. 11 is a block diagram of an apparatus in the form of a computing system including a memory device in accordance with a number of embodiments of the present disclosure.

### DETAILED DESCRIPTION

Embodiments of the present disclosure describe forming in tier multiplexers in vertical three dimensional (3D) memory. A multiplexer device or devices are formed in the uppermost levels (e.g., tiers) of an array of vertically stacked memory cells. The multiplexer device can be coupled to a global digit line via a global digit line contact that allows the memory cells in the vertical stack of memory cells to be accessed. Forming the multiplexer device in tier (e.g., in a level of the vertical stack of memory cells) can eliminate the need to form additional multiplexer circuitry on other portions of the wafer which can reduce the footprint and cost when forming the array of memory cells. The multiplexer device can be formed using the process flow of forming a memory cell access device. The multiplexer device can be formed with source/drain regions having increased doping concentrations to allow the multiplexer device to have an increased source drain width and decreased channel region length resulting improved current (Ion) performance when compared to access devices of the memory cells in the array of vertically stacked memory cells and/or multiplexer devices that are located outside of the array of vertically stacked memory cells. The multiplexer device can include a multiplexer, a demultiplexer, a multiplexer/demultiplexer, and/or a bleeder device in various embodiments of the present disclosure. The multiplexer device can be an access device that allows circuitry (e.g., logic circuitry) coupled to the multiplexer to sense, write, and/or access memory cells in the memory array.

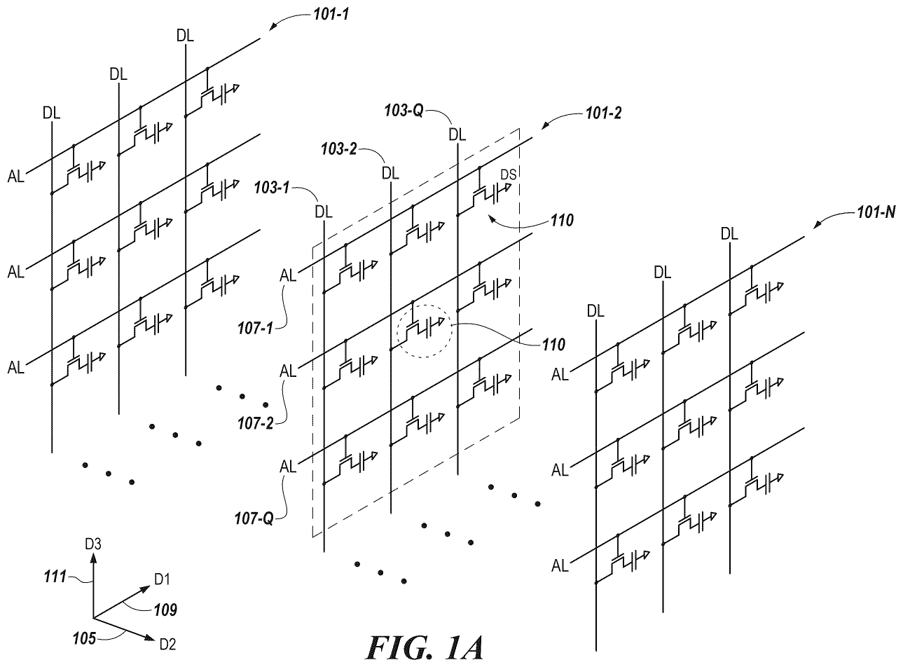

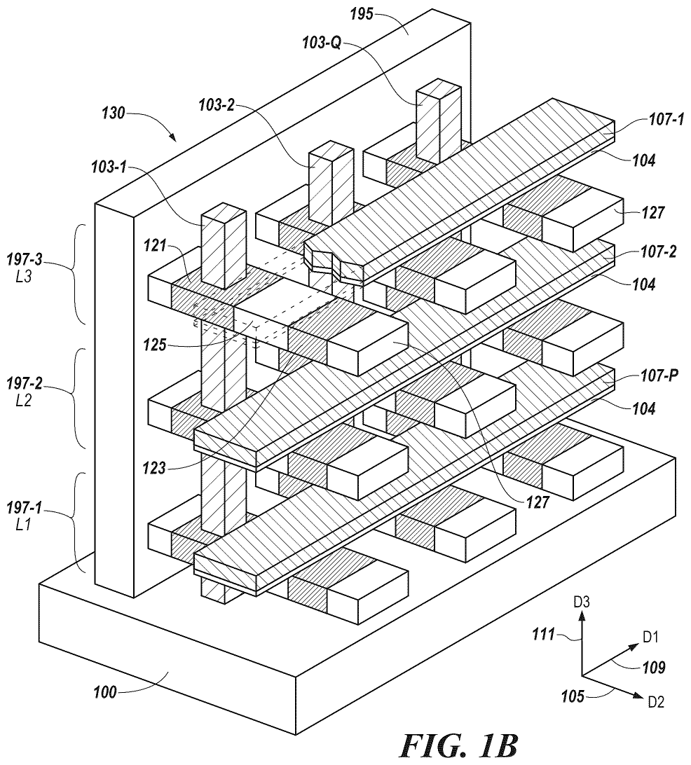

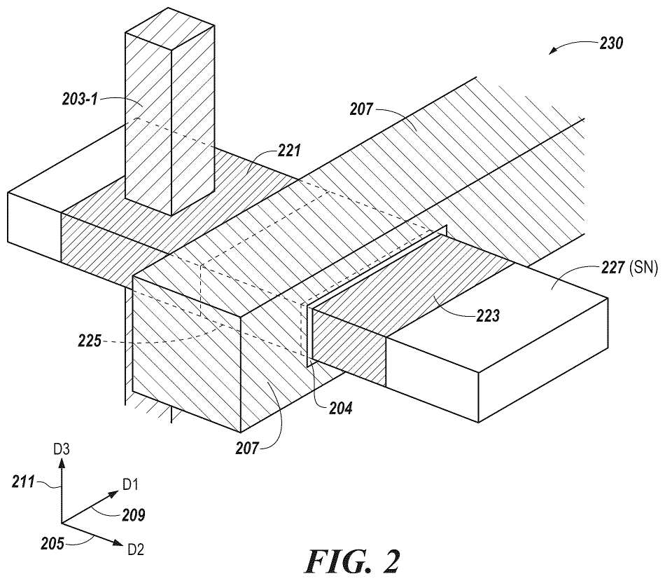

The figures herein follow a numbering convention in which the first digit or digits correspond to the figure number of the drawing and the remaining digits identify an element or component in the drawing. Similar elements or components between different figures may be identified by the use of similar digits. For example, reference numeral 104 may reference element “04” in FIG. 1, and a similar element may be referenced as 204 in FIG. 2. Multiple analogous elements within one figure may be referenced with a reference numeral followed by a hyphen and another numeral or a letter. For example, 302-1 may reference element 302-1 in FIGS. 3 and 302-2 may reference element 302-2, which may be analogous to element 302-1. Such analogous elements may be generally referenced without the hyphen and extra numeral or letter. For example, elements 302-1 and 302-2 or other analogous elements may be generally referenced as 302.

FIG. 1A is a schematic illustration of a horizontal access device in a vertical three-dimensional (3D) memory in accordance with a number of embodiments of the present disclosure. FIG. 1A illustrates a circuit diagram showing a cell array of a 3D semiconductor memory device according to embodiments of the present disclosure. FIG. 1A illustrates that a cell array may have a plurality of sub cell arrays 101-1, 101-2, . . . , 101-N. The sub cell arrays 101-1, 101-2, . . . , 101-N may be arranged along a second direction (D2) 105. Each of the sub cell arrays, e.g., sub cell array 101-2, may include a plurality of access lines 107-1, 107-2, . . . , 107-Q (which also may be referred to as word lines). Also, each of the sub cell arrays, e.g., sub cell array 101-2, may include a plurality of digit lines 103-1, 103-2, . . . , 103-Q (which also may be referred to as bit lines, data lines, or sense lines). In FIG. 1A, the access lines 107-1, 107-2, . . . , 107-Q are illustrated extending in a first direction (D1) 109 and the digit lines 103-1, 103-2, . . . , 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digit lines 103-1, 103-2, . . . , 103-Q are extending in a vertical direction, e.g., third direction (D3) 111.

A memory cell, e.g., memory cell 110, may include an access device, e.g., access transistor, and a storage node located at an intersection of each access line 107-1, 107-2, . . . , 107-Q and each digit line 103-1, 103-2, . . . , 103-Q. Memory cells may be written to, or read from, using the access lines 107-1, 107-2, . . . , 107-Q and digit lines 103-1, 103-2, . . . , 103-Q. The access lines 107-1, 107-2, . . . , 107-Q may conductively interconnect memory cells along horizontal rows of each sub cell array 101-, 101-2, . . . , 101-N, and the digit lines 103-1, 103-2, . . . , 103-Q may conductively interconnect memory cells along vertical columns of each sub cell array 101-, 101-2, . . . , 101-N. One memory cell, e.g., 110, may be located between one access line, e.g., 107-2, and one digit line, e.g., 103-2. Each memory cell may be uniquely addressed through a combination of an access line 107-1, 107-2, . . . , 107-Q and a digit line 103-1, 103-2, . . . , 103-Q.

The access lines 107-1, 107-2, . . . , 107-Q may be or include conducting patterns (e.g., metal lines) disposed on and spaced apart from a substrate. The access lines 107-1, 107-2, . . . , 107-Q may extend in a first direction (D1) 109. The access lines 107-1, 107-2, . . . , 107-Q in one sub cell array, e.g., 101-2, may be spaced apart from each other in a vertical direction, e.g., in a third direction (D3) 111.

The digit lines 103-1, 103-2, . . . , 103-Q may be or include conductive patterns (e.g., metal lines) extending in a vertical direction with respect to the substrate, e.g., in a third direction (D3) 111. The digit lines in one sub cell array, e.g., 101-2, may be spaced apart from each other in the first direction (D1) 109.

A gate of a memory cell, e.g., memory cell 110, may be connected to an access line, e.g., 107-2, and a first conductive node, e.g., first source/drain region, of an access device, e.g., transistor, of the memory cell 110 may be connected to a digit line, e.g., 103-2. Each of the memory cells, e.g., memory cell 110, may be connected to a storage node, e.g., capacitor. A second conductive node, e.g., second source/drain region, of the access device, e.g., transistor, of the memory cell 110 may be connected to the storage node, e.g., capacitor. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line, e.g., 103-2, and the other may be connected to a storage node.

FIG. 1B is a perspective view illustrating a portion of a horizontal access device in vertical three dimensional (3D) memory, e.g., a portion of a sub cell array 101-2 shown in FIG. 1A as a vertically oriented stack of memory cells in an array, in accordance with a number of embodiments of the present disclosure.

As shown in FIG. 1B, a substrate 100 may have formed thereon one of the plurality of sub cell arrays, e.g., 101-2, described in connection with FIG. 1A. For example, the substrate 100 may be or include a silicon substrate, a germanium substrate, or a silicon-germanium substrate, etc. Embodiments, however, are not limited to these examples.

As shown in the example embodiment of FIG. 1B, the substrate 100 may have fabricated thereon a vertically oriented stack of memory cells, e.g., memory cell 110 in FIG. 1A, extending in a vertical direction, e.g., third direction (D3) 111. According to some embodiments the vertically oriented stack of memory cells may be fabricated such that each memory cell, e.g., memory cell 110 in FIG. 1A, is formed on plurality of vertical levels, e.g., a first level (L1) 197-1, a second level (L2) 197-2, and a third level (L3) 197-3. The plurality of vertical levels can include any number of levels up to an uppermost Nth level. Vertical levels can also be referred to as tiers in vertically oriented stack of memory cells. The repeating, vertical levels, L1, L2, and L3, may be arranged, e.g., “stacked”, a vertical direction, e.g., third direction (D3) 111 shown in FIG. 1A, and may be separated from the substrate 100 by an insulator material. Each of the repeating, vertical levels, L1, L2, and L3 may include a plurality of discrete components, e.g., regions, to the horizontally oriented access devices 130, e.g., transistors, and storage nodes, e.g., capacitors, including access line 107-1, 107-2, . . . , 107-Q connections and digit line 103-1, 103-2, . . . , 103-Q connections. The plurality of discrete components to the horizontally oriented access devices 130, e.g., transistors, may be formed in a plurality of iterations of vertically, repeating layers within each level, as described in more detail below, and may extend horizontally in the second direction (D2) 105, analogous to second direction (D2) 105 shown in FIG. 1A.

The plurality of discrete components to the laterally oriented access devices 130, e.g., transistors, may include a first source/drain region 121 and a second source/drain region 123 separated by a channel region 125, extending laterally in the second direction (D2) 105, and formed in a body of the access devices. In some embodiments, channel region 125 may include silicon, germanium, silicon-germanium, and/or indium gallium zinc oxide (IGZO). In some embodiments, the first and the second source/drain regions, 121 and 123, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 127, e.g., capacitor, may be connected to one respective end of the access device. As shown in FIG. 1B, the storage node 127, e.g., capacitor, may be connected to the second source/drain region 123 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1A, may similarly extend in the second direction (D2) 105, analogous to second direction (D2) 105 shown in FIG. 1A.

As shown in FIG. 1B a plurality of horizontally oriented access lines 107-1, 107-2, . . . , 107-Q extend in the first direction (D1) 109, analogous to the first direction (D1) 109 in FIG. 1A. The plurality of horizontally oriented access lines 107-1, 107-2, . . . , 107-Q may be analogous to the access lines 107-1, 107-2, . . . , 107-Q shown in FIG. 1A. The plurality of horizontally oriented access lines 107-1, 107-2, . . . , 107-Q may be arranged, e.g., “stacked”, along the third direction (D3) 111. The plurality of horizontally oriented access lines 107-1, 107-2, . . . , 107-Q may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

Among each of the vertical levels, (L1), (L2), and (L3), the horizontally oriented memory cells, e.g., memory cell 110 in FIG. 1A, may be spaced apart from one another horizontally in the first direction (D1) 109. However, the plurality of discrete components to the horizontally oriented access devices 130, e.g., first source/drain region 121 and second source/drain region 123 separated by a channel region 125, extending laterally in the second direction (D2) 105, and the plurality of horizontally oriented access lines 107-1, 107-2, . . . , 107-Q extending laterally in the first direction (D1) 109, may be formed within different vertical layers within each level. For example, the plurality of horizontally oriented access lines 107-1, 107-2, . . . , 107-Q, extending in the first direction (D1) 109, may be formed on a top surface opposing and electrically coupled to the channel regions 125, separated therefrom by a gate dielectric, and orthogonal to horizontally oriented access devices 130, e.g., transistors, extending in laterally in the second direction (D2) 105. In some embodiments, the plurality of horizontally oriented access lines 107-1, 107-2, . . . , 107-Q, extending in the first direction (D1) 109 are formed in a higher vertical layer, farther from the substrate 100, within a level, e.g., within level (L1), than a layer in which the discrete components, e.g., first source/drain region 121 and second source/drain region 123 separated by a channel region 125, of the horizontally oriented access device are formed.

As shown in the example embodiment of FIG. 1B, the digit lines, 103-1, 103-2, . . . , 103-Q, extend in a vertical direction with respect to the substrate 100, e.g., in a third direction (D3) 111. Further, as shown in FIG. 1B, the digit lines, 103-1, 103-2, . . . , 103-Q, in one sub cell array, e.g., sub cell array 101-2 in FIG. 1A, may be spaced apart from each other in the first direction (D1) 109. The digit lines, 103-1, 103-2, . . . , 103-Q, may be provided, extending vertically relative to the substrate 100 in the third direction (D3) 111 in vertical alignment with source/drain regions to serve as first source/drain regions 121 or, as shown, be vertically adjacent first source/drain regions 121 for each of the horizontally oriented access devices 130, e.g., transistors, extending laterally in the second direction (D2) 105, but adjacent to each other on a level, e.g., first level (L1), in the first direction (D1) 109. Each of the digit lines, 103-1, 103-2, . . . , 103-Q, may vertically extend, in the third direction (D3), on sidewalls, adjacent first source/drain regions 121, of respective ones of the plurality of horizontally oriented access devices 130, e.g., transistors, that are vertically stacked. In some embodiments, the plurality of vertically oriented digit lines 103-1, 103-2, . . . , 103-Q, extending in the third direction (D3) 111, may be connected to side surfaces of the first source/drain regions 121 directly and/or through additional contacts including metal silicides.

For example, a first one of the vertically extending digit lines, e.g., 103-1, may be adjacent a sidewall of a first source/drain region 121 to a first one of the horizontally oriented access devices 130, e.g., transistors, in the first level (L1), a sidewall of a first source/drain region 121 of a first one of the horizontally oriented access devices 130, e.g., transistors, in the second level (L2), and a sidewall of a first source/drain region 121 a first one of the horizontally oriented access devices 130, e.g., transistors, in the third level (L3), etc. Similarly, a second one of the vertically extending digit lines, e.g., 103-2, may be adjacent a sidewall to a first source/drain region 121 of a second one of the horizontally oriented access devices 130, e.g., transistors, in the first level (L1), spaced apart from the first one of horizontally oriented access devices 130, e.g., transistors, in the first level (L1) in the first direction (D1) 109. And the second one of the vertically extending digit lines, e.g., 103-2, may be adjacent a sidewall of a first source/drain region 121 of a second one of the laterally oriented access devices 130, e.g., transistors, in the second level (L2), and a sidewall of a first source/drain region 121 of a second one of the horizontally oriented access devices 130, e.g., transistors, in the third level (L3), etc. Embodiments are not limited to a particular number of levels.

The vertically extending digit lines, 103-1, 103-2, . . . , 103-Q, may include a conductive material, such as, for example, one of a doped semiconductor material, a conductive metal nitride, metal, and/or a metal-semiconductor compound. The digit lines, 103-1, 103-2, . . . , 103-Q, may correspond to digit lines (DL) described in connection with FIG. 1A.

As shown in the example embodiment of FIG. 1B, a conductive body contact may be formed extending in the first direction (D1) 109 along an end surface of the horizontally oriented access devices, e.g., transistors, in each level (L1), (L2), and (L3) above the substrate 100. The body contact may be connected to a body e.g., body region, of the horizontally oriented access devices, e.g., transistors, in each memory cell, e.g., memory cell 110 in FIG. 1A. The body contact may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2 illustrates a portion of a horizontal access device in vertical three-dimensional (3D) memory in accordance with a number of embodiments of the present disclosure. FIG. 2 illustrates in more detail a unit cell, e.g., memory cell 110 in FIG. 1, of the vertically stacked array of memory cells, e.g., within a sub cell array 101-2 in FIG. 1, according to some embodiments of the present disclosure. As shown in FIG. 2, the first and the second source/drain regions, 221 and 223, may be impurity doped regions to the laterally oriented access devices 230, e.g., transistors. The first and the second source/drain regions may be separated by channel region 225 formed in a body of semiconductor material, e.g., body region of the horizontally oriented access devices 230, e.g., transistors. The first and the second source/drain regions, 221 and 223, may be formed from an n-type or p-type dopant doped in the body region. However, embodiments are not so limited.

For example, for an n-type conductivity transistor construction the body region of the laterally oriented access devices 230, e.g., transistors, may be formed of a low doped p-type (p−) semiconductor material. In one embodiment, the body region and the channel region 225 separating the first and the second source/drain regions, 221 and 223, may include a low doped, p-type (e.g., low dopant concentration (p−)) polysilicon (Si) material consisting of boron (B) atoms as an impurity dopant to the polycrystalline silicon. The first and the second source/drain regions, 221 and 223, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In2O3), or indium tin oxide (In2-xSnxO3), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 221 and 223, may include a high dopant concentration, n-type conductivity impurity (e.g., high dopant (n+)) doped in the first and the second source/drain regions, 221 and 223. In some embodiments, the high dopant, n-type conductivity first and second drain regions 221 and 223 may include a high concentration of phosphorus (P) atoms deposited therein. Embodiments, however, are not limited to this example. In other embodiments, the horizontally oriented access devices 230, e.g., transistors, may be of a p-type conductivity construction in which case the impurity, e.g., dopant, conductivity types would be reversed.

As shown in FIG. 2, the first and the second source/drain regions, 221 and 223, may be impurity doped regions to the laterally oriented access devices 230, e.g., transistors. The first and the second source/drain regions may be separated by channel region 225 formed in a body of semiconductor material, e.g., body region, of the horizontally oriented access devices 230, e.g., transistors. The first and the second source/drain regions, 221 and 223, may be formed from an n-type or p-type dopant doped in the body region. However, embodiments are not so limited.

The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 221 and is in electrical contact with the body contact. Further, as shown in the example embodiment of FIG. 2, an access line, e.g., 207, analogous to the access lines 107-1, 107-2, . . . , 107-Q shown in FIG. 1, may disposed on a top surface opposing and coupled to a channel region 225, separated therefrom by a gate dielectric 204. Gate dielectric 204 may be, for example, a high-k dielectric material, a silicon oxide material, a silicon nitride material, a silicon oxynitride material, etc., or a combination thereof. Embodiments are not so limited. For example, in high-k dielectric material examples the gate dielectric material 304 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 2, a digit line, e.g., 203-1, analogous to the digit lines 103-1, 103-2, . . . , 103-Q in FIG. 1, may be vertically extending in the third direction (D3) 211 adjacent a sidewall of the first source/drain region 221 in the body to the horizontally oriented access devices 230, e.g., transistors horizontally conducting between the first and the second source/drain regions 221 and 223 along the second direction (D2) 205. In this embodiment, the vertically oriented digit line 203-1 is formed symmetrically, in vertical alignment, in electrical contact with the first source/drain region 221. The digit line 203-1 may be formed in contact with an insulator material such that there is no body contact within channel region 225.

As shown in the example embodiment of FIG. 2, the digit line 203-1 may be formed symmetrically within the first source/drain region 221 such that the first source/drain region 221 surrounds the digit line 203-1 all around. The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 321 and is in contact with the body contact. An insulator material may fill the body contact such that the first source/drain region 221 may not be in electrical contact with channel region 225. Further, as shown in the example embodiment of FIG. 2, an access line, e.g., 207, analogous to the access lines 107-1, 107-2, . . . , 107-Q shown in FIG. 1, may disposed all around and coupled to a channel region 225, separated therefrom by a gate dielectric 204.

Although the digit line 203-1 is described above as being formed symmetrically within the first source/drain region 221 such that the first source/drain region 221 surrounds the digit line 203-1 all around, embodiments are not so limited. For instance, in some examples, the digit line 203-1 can be formed asymmetrically. In this embodiment, the vertically oriented digit line is formed asymmetrically adjacent in electrical contact with the first source/drain regions 221. The digit line may be formed asymmetrically to reserve room for a body contact in the channel region 225.

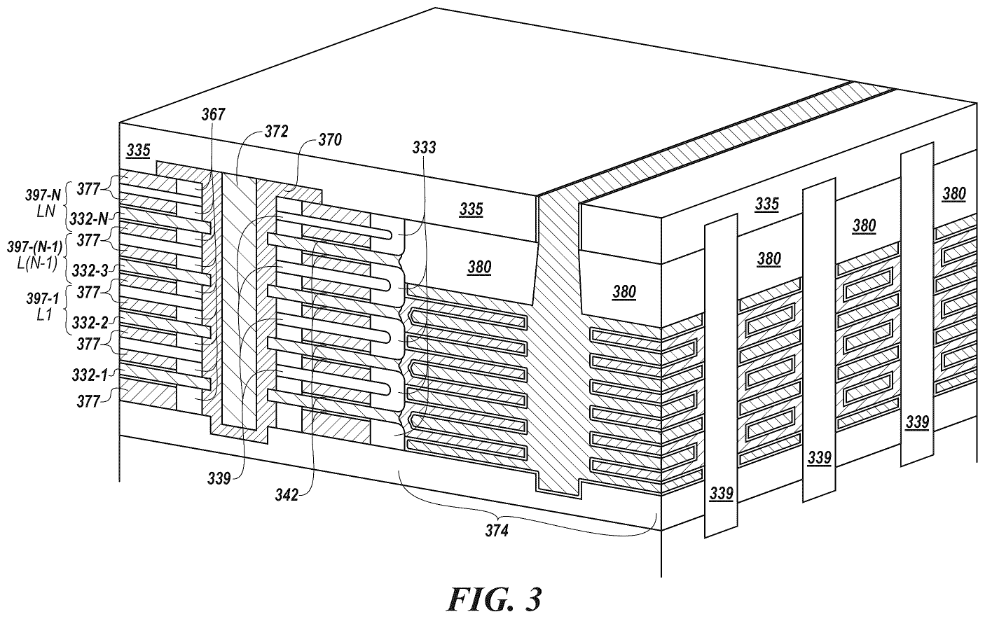

FIG. 3 is a perspective view of a memory device in accordance with a number of embodiments of the present disclosure. FIG. 3 includes first conductive material 377, an Si material 332, a photolithographic mask material (e.g., mask material) 335, an interlayer dielectric (ILD) fill material 367, a second conductive material 370, a metal material 372, a first dielectric material 339, a second dielectric material 333, a second interlayer dielectric material 342, and a plurality of storage nodes (e.g., capacitors) 374.

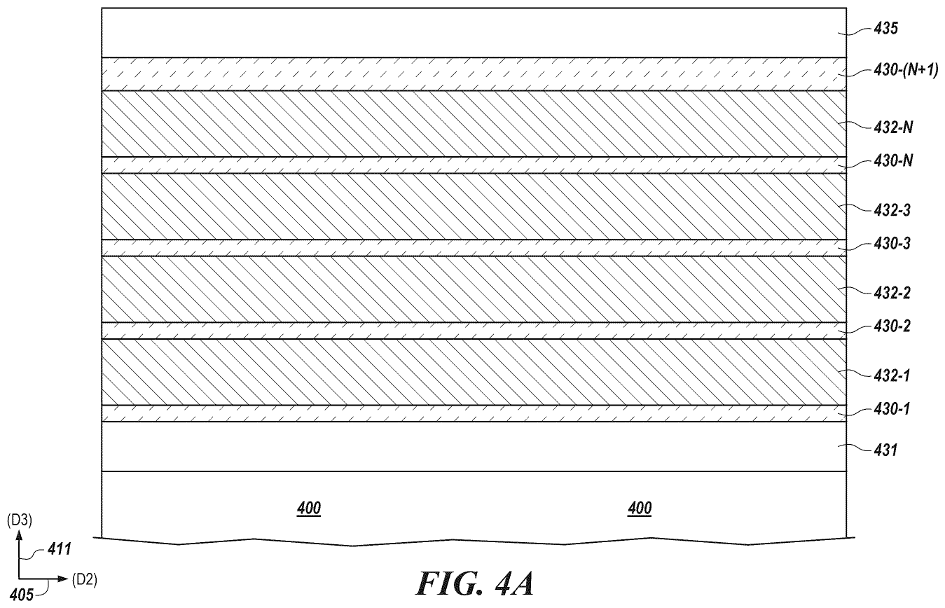

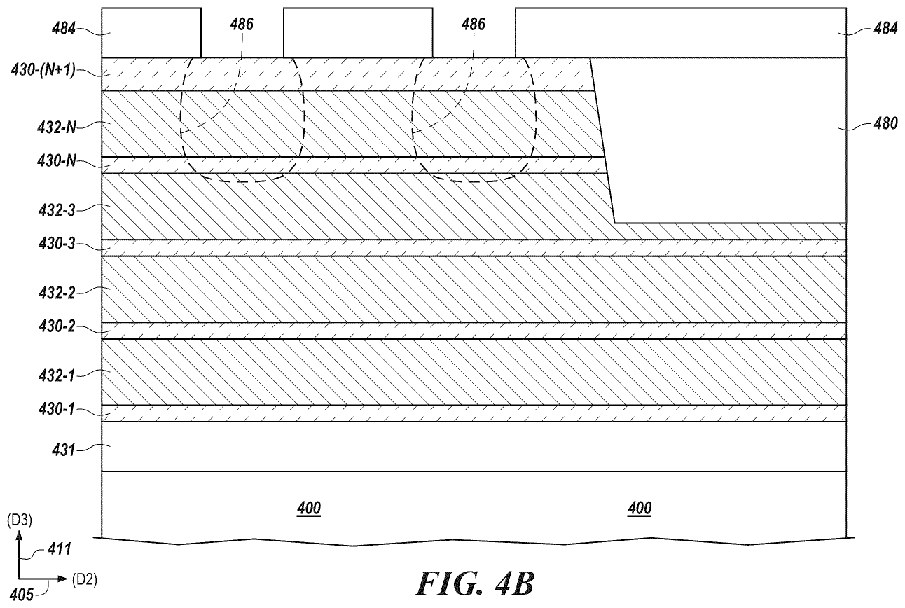

FIG. 3 illustrates a portion of a vertical 3D memory array that is formed in accordance with the process described in FIGS. 4-16, as is further described herein. The 3D memory array can include an array of vertically stacked memory cells having a plurality of levels, such as N levels. FIG. 3 can include level L1 397-1 up to the uppermost levels, levels L (N−1) 397-(N−1) and LN 397-N. The uppermost levels, L (N−1) 397-(N−1) and L-N 397-N can include a multiplexer device and each level of the plurality of levels below the multiplexer device can include memory cells with horizontally oriented access devices and storage nodes. In the storage node region, the uppermost levels, levels L (N−1) 397-(N−1) and LN 397-N, can include an isolation region 380. Isolation region 380 replaces and prevents storage node from being formed in the uppermost levels, levels L (N−1) 397-(N−1) and LN 397-N, such that the access device, the multiplexer device, in the uppermost level L-N 397-N is not horizontally coupled to a storage node and acts an a multiplexer device coupled to a global access line.

Each storage node can include horizontally oriented access devices having first source/drain regions and second source/drain regions separated by channel regions, and gates on a gate dielectric material. The array can further comprise horizontally oriented access lines forming the gates to the horizontally oriented access devices. The horizontally oriented access lines can be gate all around (GAA) structures. The storage nodes can further include horizontally oriented storage nodes electrically coupled to the second source/drain regions of the horizontally oriented access devices.

The horizontal access devices of the vertical 3D memory array can include the second dielectric material 333, the first dielectric material 377, a first dielectric material 339, and ILD fill material 367. The access devices can be coupled to the plurality of storage nodes 374. In some embodiments, the plurality of storage nodes 374 can be double-sided capacitors. The access devices can be used to transfer current between the metal material 372 and the plurality of storage nodes 374.

Further included in the vertical 3D memory array can be epitaxially formed vertical digit lines 392 connected to the first source/drain regions of the horizontally oriented access devices. Devices and methods of forming the epitaxially grown vertical digit lines are further described herein.

FIGS. 4A to 4B illustrate a cross-sectional view, at one stage of a semiconductor fabrication process, for forming vertical three-dimensional (3D) memory, such as illustrated in FIGS. 1-3, in accordance with a number of embodiments of the present disclosure.

In the example embodiment shown in the example of FIG. 4, the method comprises forming alternating layers of a silicon germanium (SiGe) material, 430-1, 430-2, . . . , 430-N (collectively referred to as silicon germanium (SiGe) 430), and a silicon (Si) material, 432-1, 432-2, . . . , 432-N (collectively referred to as epitaxially grown, single crystalline silicon (Si) material 432), in repeating iterations to form a vertical stack 402 on a working surface of a semiconductor substrate 400. In one embodiment, the silicon germanium (SiGe) 430 can be deposited on a dielectric 431 to have a thickness, e.g., vertical height in the third direction (D3), in a range of five (5) nm to thirty (30) nm. In one embodiment, the silicon 432 can be deposited to have a thickness (t2), e.g., vertical height, in a range of thirty (30) nanometers (nm) to sixty (60) nm. Embodiments, however, are not limited to these examples. As shown in FIG. 4, a vertical direction 411 is illustrated as a third direction (D3), e.g., z-direction in an x-y-z coordinate system, analogous to the third direction (D3), among first, second, and third directions, shown in FIGS. 1-2.

In some embodiments, the silicon germanium (SiGe), 430-1, 430-2, . . . , 430-N, may be a mix of silicon and germanium. By way of example, and not by way of limitation, the silicon germanium (SiGe) 430 may be grown on a dielectric 431 by way of epitaxial growth. Embodiments are not limited to these examples. In some embodiments, the single crystalline silicon (Si) material, 432-1, 432-2, . . . , 432-N, may comprise a silicon (Si) material in a polycrystalline and/or amorphous state. The single crystalline silicon (Si) material, 432-1, 432-2, . . . , 432-N, may be a low doped, p-type (p−) epitaxially grown, single crystalline silicon (Si) material. The silicon material, 432-1, 432-2, . . . , 432-N, may also be formed by epitaxially growth on the silicon germanium (SiGe) 430. After the epitaxially grown silicon germanium (SiGe) 430 has been formed, the seed is turned to pure silicon. Embodiments, however, are not limited to these examples.

The repeating iterations of alternating silicon germanium (SiGe), 430-1, 430-2, . . . , 430-N layers and epitaxially grown, single crystalline silicon (Si) material, 432-1, 432-2, . . . , 432-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of epitaxially grown silicon germanium (SiGe) and epitaxially grown, single crystalline silicon (Si) material, in repeating iterations to form the vertical stack 402.

The layers may occur in repeating iterations vertically. In the example of FIG. 4, numbered 1, 2, 3, N, and N+1 of the repeating iterations are shown. For example, the stack may include: a first silicon germanium (SiGe) 430-1, a first Si material 432-1, a second SiGe material 430-2, a second Si material 432-2, a third SiGe material 430-3, and a Si material 432-3, in further repeating iterations. Embodiments, however, are not limited to this example and more or fewer repeating iterations may be included.

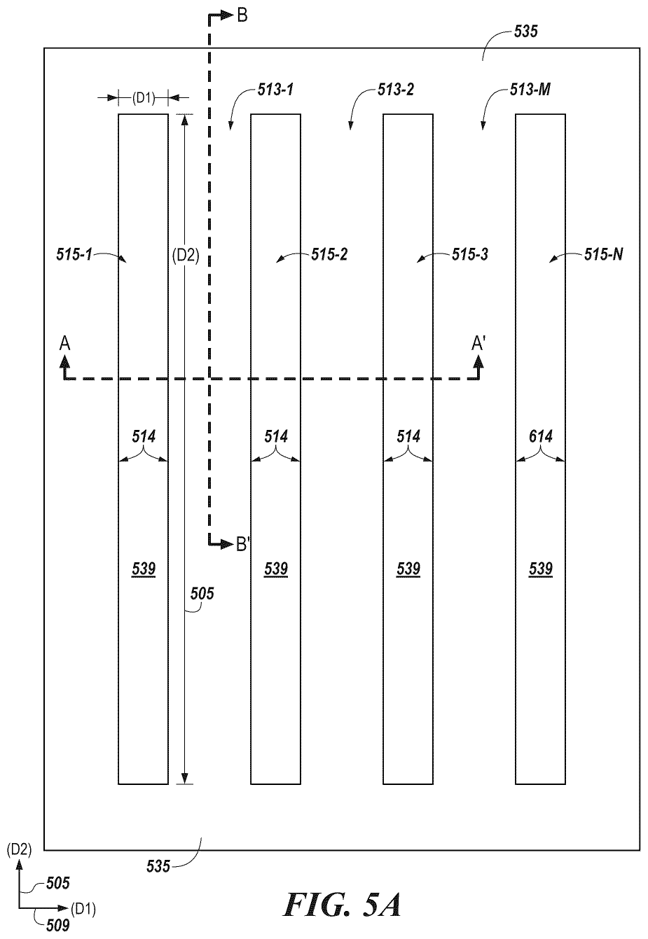

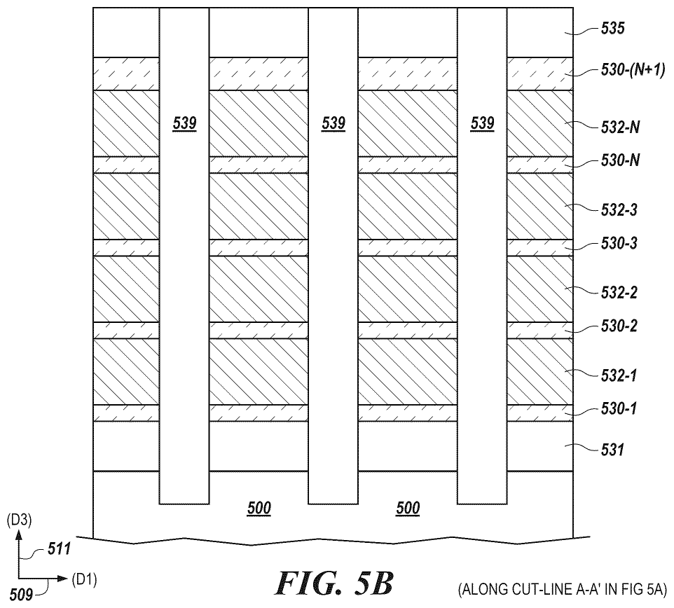

In FIG. 4B, SiGe layer 430-(N+1), SiGe layer 430-N, and Si layer 432-N, and/or Si layer 432-3 can be replaced with isolation region 480 in portion of the vertical stack 402 where storage nodes will be formed. The isolation region 480 can prevent storage nodes from being formed in the upper levels of the array of vertically stacked memory cells so that the multiplexer device in the uppermost levels in the array of vertically stacked memory cells are not horizontally adjacent to a storage node. Isolation regions 580, 680, 780, 880, and 980 in FIGS. 5A-9C can be formed to prevent the formation of storage nodes in the uppermost levels of the array of vertically stacked memory cells during semiconductor fabrication process described in FIGS. 5A-9C.

Also, in FIG. 4B, a mask 484 with openings can be formed on the vertical stack 402. The SiGe layer 430-(N+1), SiGe layer 430-N, and Si layer 432-N, and/or Si layer 432-3 can be doped with an increased doping concentration 486. The increased doping concentration 486 in the 430-(N+1), silicon germanium layer 430-N, and silicon layer 432-N, and/or silicon layer 430-3 can cause the multiplexer device that will be formed in the uppermost levels of array of vertically stacked memory cells to have wider source/drain regions and a shorter channel length (cL) in the channel regions than the access devices of the memory cells in the array of vertically stacked memory cells below the multiplexer device.

FIGS. 5A to 5B illustrate an example method, at one stage of a semiconductor fabrication process, for forming vertical three-dimensional (3D) memory, such as illustrated in FIGS. 1-3, in accordance with a number of embodiments of the present disclosure.

FIG. 5A illustrates a top-down view of a semiconductor structure, at a particular point in time, in a semiconductor fabrication process, according to one or more embodiments. In the example embodiment shown in the example of FIG. 5A, the method comprises using an etchant process to form a plurality of vertical openings 515 (e.g., a plurality of second vertical openings), having a first horizontal direction (D1) 509 and a second horizontal direction (D2) 505, through the vertical stack to the substrate. In one example, as shown in FIG. 5A, the plurality of vertical openings 515 are extending predominantly in the second horizontal direction (D2) 505 and may form elongated vertical, pillar columns 513-1, 513-2, . . . , 513-M (collectively and/or independently referred to as 513), with sidewalls 514 in the vertical stack. The plurality of first vertical openings 500 may be formed using photolithographic techniques to pattern a photolithographic mask 535, e.g., to form a hard mask (HM), on the vertical stack prior to etching the plurality of first vertical openings 515. Similar semiconductor process techniques may be used at other points of the semiconductor fabrication process described herein.

The semiconductor fabrication process can further include doping a first source/drain region of the Si material 532. That is, the first Si material 532-1, the second Si material 532-2, the third Si material 532-3, and in further repeating iterations, can be doped. For example, a source/drain region may be formed by gas phase doping a dopant into a side surface portion of the Si material 532. In some embodiments, the source/drain region may be a first source/drain region that will connect to a digit line connection. In one example, gas phase doping may be used to achieve a highly isotropic (e.g., non-directional doping), to form the first source/drain regions for the horizontally oriented access devices. In another example, thermal annealing with doping gas, such as phosphorous (P) may be used with a high energy plasma assist to break the bonding. Embodiments, however, are not so limited and other suitable semiconductor fabrication techniques may be utilized.

The openings 515 may be filled with a dielectric material 539. In one example, a spin on dielectric process may be used to fill the openings 515. In one embodiment, the dielectric material 539 may be an oxide material. However, embodiments are not so limited.

FIG. 5B is a cross sectional view, taken along cut-line A-A′ in FIG. 5A, showing another view of the semiconductor structure at a particular time in the semiconductor fabrication process. The cross-sectional view shown in FIG. 5B shows the repeating iterations of alternating layers of silicon germanium (SiGe) 530 and silicon (Si) material 532 on a semiconductor substrate 500 to form the vertical stack, e.g., 402 as shown in FIG. 4.

As shown in FIG. 5B, a plurality of vertical openings may be formed through the layers within the vertically stacked memory cells to expose vertical sidewalls in the vertical stack and form elongated vertical pillar columns 513 and then filled with a first dielectric material 539. The vertical openings may be formed through the repeating iterations of the silicon germanium (SiGe) 530 and the silicon (Si) material 532.

The vertical openings may be formed to expose vertical sidewalls in the vertical stack. The vertical openings may extend in a second horizontal direction (D2) 505 to form the elongated vertical, pillar columns with first vertical sidewalls in the vertical stack and then filled with the dielectric material 539.

As shown in FIG. 5B, a first dielectric material 539, such as an oxide or other suitable spin on dielectric (SOD), may be deposited in the vertical openings, using a process such as CVD, to fill the vertical openings. First dielectric material 539 may also be formed from a silicon nitride (Si3N4) material. In another example, the first dielectric material 539 may include silicon oxy-nitride (SiOxNy), and/or combinations thereof. Embodiments are not limited to these examples. The plurality of first vertical openings may be formed using photolithographic techniques to pattern a photolithographic mask 535, e.g., to form a hard mask (HM), on the vertical stack prior to etching the plurality of first vertical openings. In one embodiment, hard mask 535 may be deposited over silicon germanium (SiGe) 530. Similar semiconductor process techniques may be used at other points of the semiconductor fabrication process described herein.

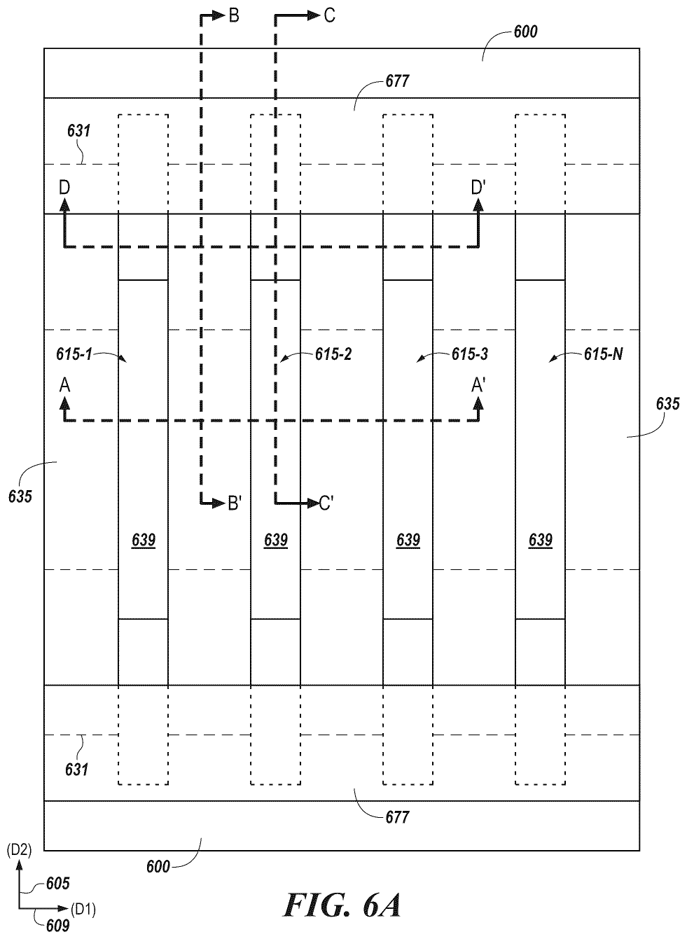

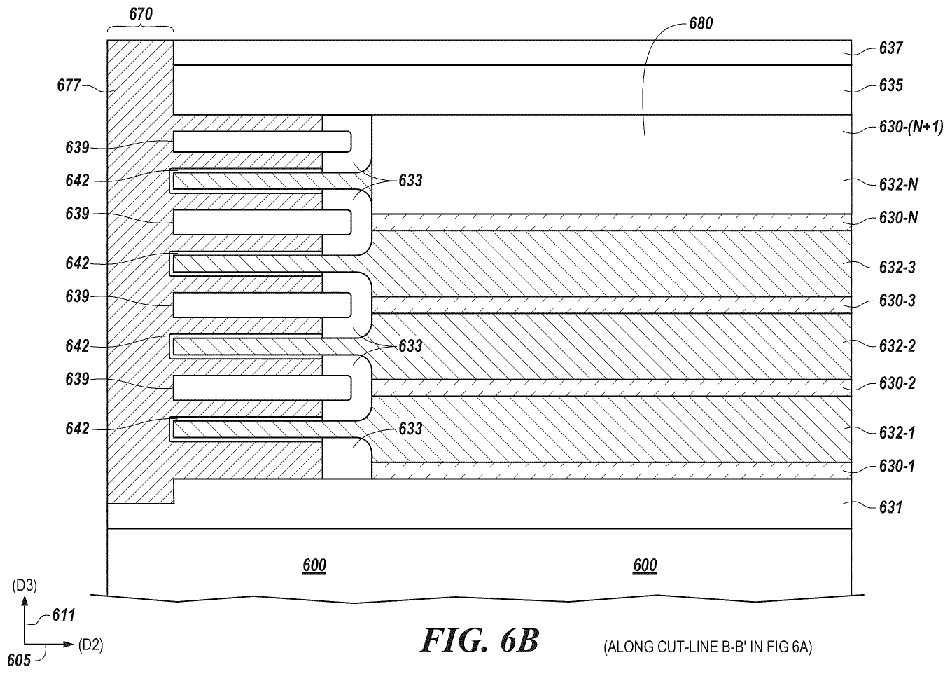

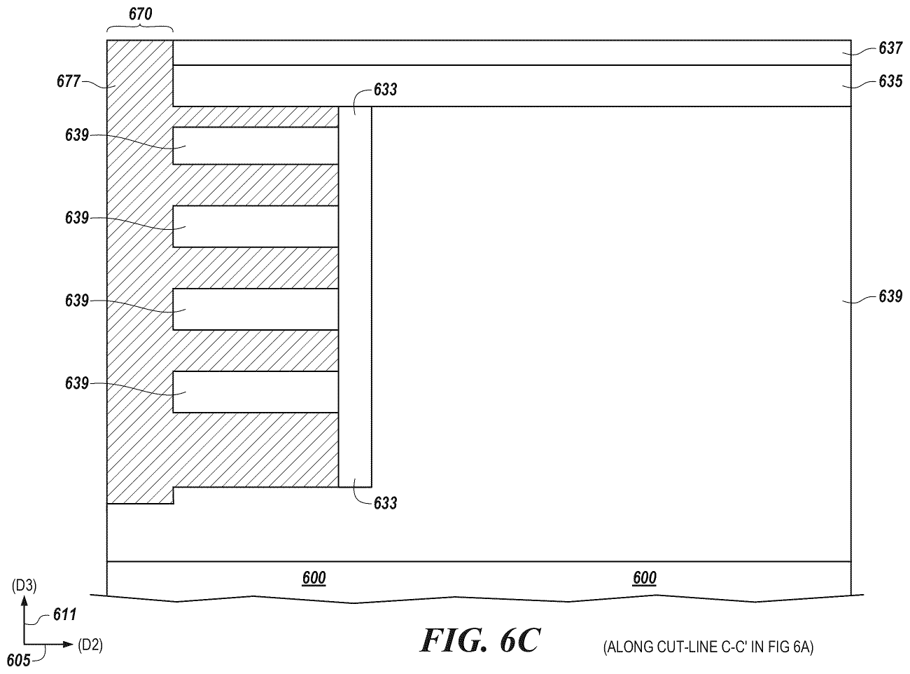

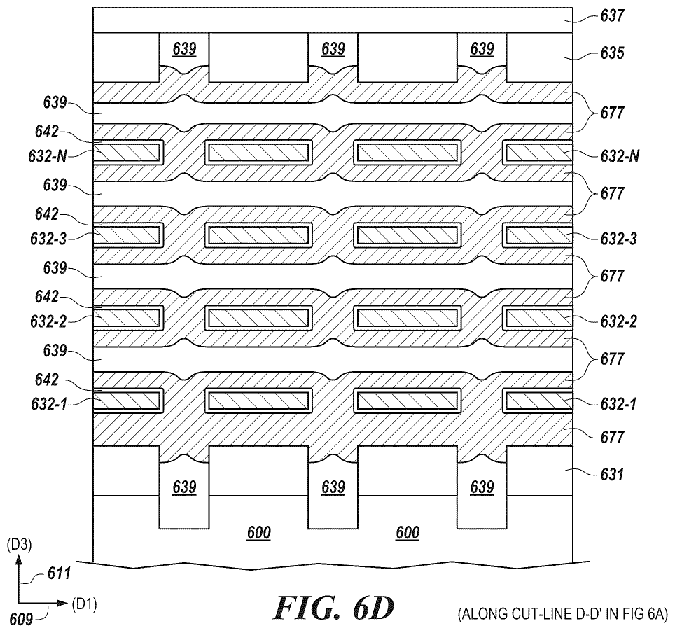

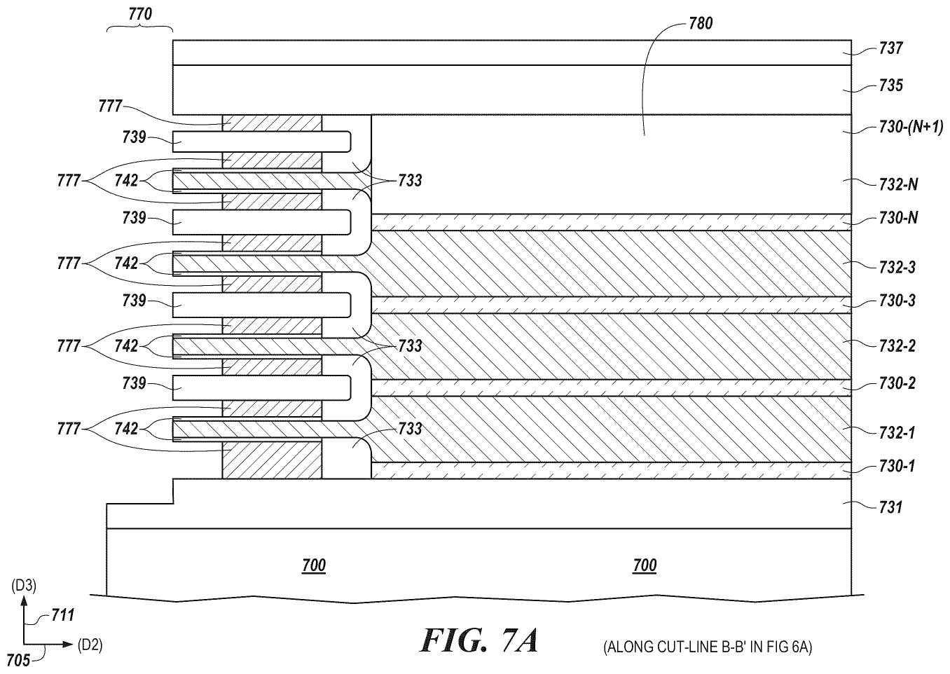

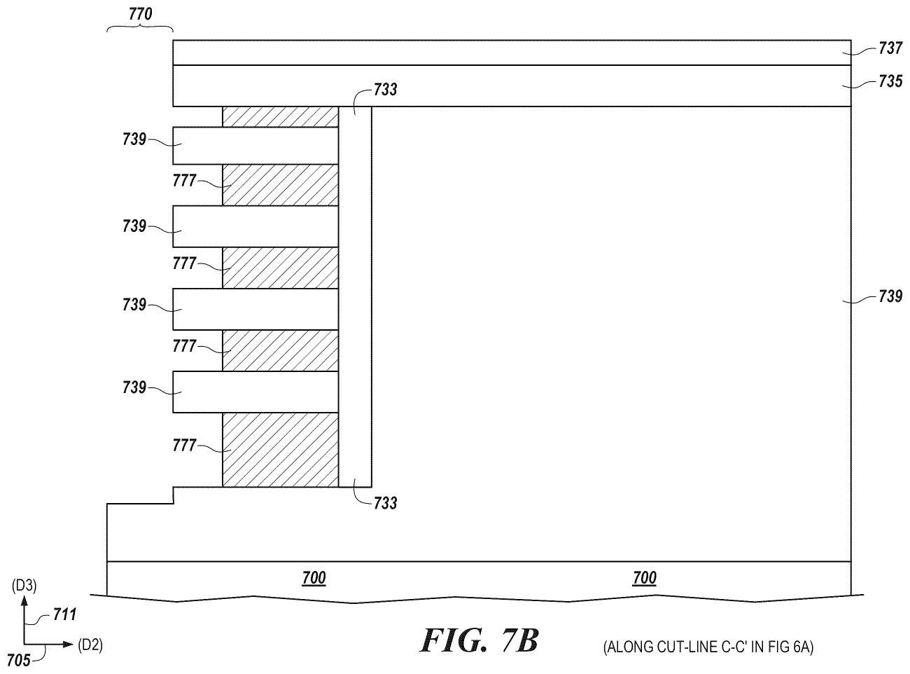

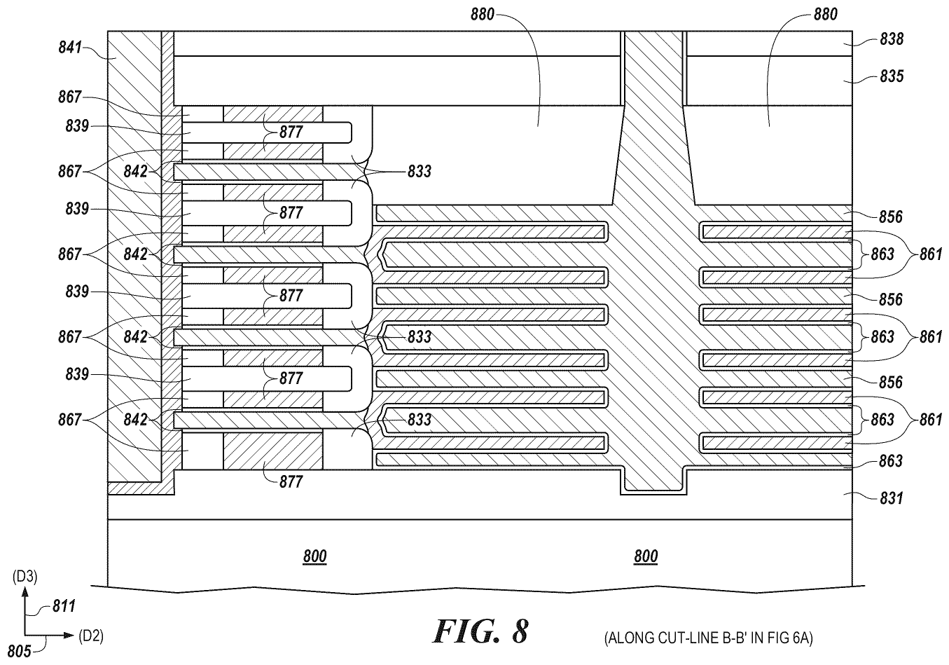

FIGS. 6A to 6D illustrate an example method, at another stage of a semiconductor fabrication process, for forming vertical three-dimensional (3D) memory in accordance with a number of embodiments of the present disclosure.

FIG. 6A illustrates an example method, at another stage of a semiconductor fabrication process for forming bifurcated access line contacts in vertical three dimensional (3D) memory, in accordance with a number of embodiments of the present disclosure. FIG. 6A illustrates a top down view of a semiconductor structure, at a particular point in time, in a semiconductor fabrication process, according to one or more embodiments. In the example embodiment of FIG. 6A, the method comprises using a photolithographic process to pattern the photolithographic mask 635. A first conductive material 677 may be deposited above the vertical openings 631. The first conductive material 677 may be deposited in the continuous first horizontal openings to form horizontally oriented access lines opposing channel regions of the single crystalline silicon (Si) material 632.

FIG. 6B illustrates a cross sectional view, taken along cut-line B-B′ in FIG. 6A, showing another view of the semiconductor structure at this particular point in one example semiconductor fabrication process for forming bifurcated access line contacts in vertical three dimensional (3D) memory in accordance with embodiments of the present disclosure. The cross sectional view shown in FIG. 6B is illustrated extending in the second horizontal direction (D2) 605, left and right along the plane of the drawing sheet, along an axis of the repeating iterations of alternating layers of the silicon germanium (SiGe) material 630 and the single crystalline silicon (Si) material 632.

A process of depositing and etching materials is used to form the structure shown in FIG. 6B. In some embodiments, the process of depositing and etching materials can include forming horizontally oriented access devices and horizontally oriented storage nodes (e.g., storage nodes 226 in FIG. 2) at each level of the vertical stack (e.g., vertical stack 501 in FIG. 5) to form an array of vertically stacked memory cells. Each of the horizontally oriented access devices can have first source/drain regions and second source/drain regions separated by channel regions. In some embodiments, gates can be formed fully around every surface of the channel regions as gate all around (GAA) structures on a gate dielectric material. Further, in some embodiments, the second source/drain regions can be coupled to storage nodes.

The semiconductor structure shown in FIG. 6B shows the semiconductor structure after the silicon germanium (SiGe) layers are selectively etched to form a plurality of first horizontal openings a first length from first vertical openings 660. In some embodiments, the second vertical openings 660 can be formed to a depth in a range of 0.5 to one (1) micrometer (μm). Further, in some embodiments, each of the first vertical openings 660 can be formed to have an aspect ratio in a range of 15-20. In some embodiments, the selective etch that forms to plurality of second horizontal openings can also reduce a vertical thickness of the silicon (Si) layers. In some embodiments, a vertical thickness of a portion of each of the silicon (Si) layers can be reduced to a vertical thickness in a range of 100-150 Angstroms (Å).

The process of forming the horizontally oriented access devices can further include conformally depositing a second dielectric material 633 on exposed surfaces in the plurality of first horizontal openings and depositing the first dielectric material 639 to fill the plurality of first horizontal openings. The second dielectric material 639 can be selectively etched from the plurality of first horizontal openings a second length (L2) from the first vertical opening 660. In some embodiments, the second length (L2) can be a length in a range of 130-160 nanometers (nm).

A first conductive material 677 may be deposited in the first horizontal opening on gate dielectric material 642 after selectively etching the second dielectric material 639. The first conductive material 677 may be deposited around the single crystalline silicon (Si) material 632 such that the first conductive material 677 may have a top portion above the single crystalline silicon (Si) material 632 and a bottom portion below the single crystalline silicon (Si) material to form a gate all around (GAA) gate structure, at a channel of an access device region. The first conductive material 677 may be conformally deposited into vertical openings 660 and fill the continuous horizontal openings up to the unetched portions of the oxide material 642, the first dielectric material 639, and the dielectric material 633. Conductive material 677 may be conformally deposited using a chemical vapor deposition (CVD) process, plasma enhanced CVD (PECVD), atomic layer deposition (ALD), or other suitable deposition process.

In some embodiments, the first conductive material, 677, may comprise one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The first conductive material 677 entwined with the gate dielectric material may form horizontally oriented access lines opposing a channel region of the single crystalline silicon (Si) material (which also may be referred to aa word lines).

FIG. 6C illustrates a cross sectional view, taken along cut-line C-C′ in FIG. 6A, showing another view of the semiconductor structure at this particular point in one example semiconductor fabrication process of an embodiment of the present disclosure. The cross sectional view shown in FIG. 6C is illustrated extending in the second horizontal direction (D2) 605, left and right in the plane of the drawing sheet, along an axis of the repeating iterations of alternating layers of continuous horizontal openings and single crystalline silicon (Si) material 632.

In FIG. 6C, first dielectric material 639 is shown spaced along a second horizontal direction (D2) 605, extending into and out from the plane of the drawings sheet, for a three dimensional (3D) array of vertically oriented memory cells. At the left end of the drawing sheet is shown the repeating iterations of alternating layers of single crystalline silicon (Si) material 632, separated by continuous horizontal openings in a first direction (D1) 609 filled with a first conductive material 677. The first conductive material 677 may be conformally deposited into vertical openings 660 and into the horizontal openings. The first conductive material 677 is formed on the gate dielectric material (e.g., gate dielectric material 642 in FIG. 6B). At the right hand of the drawing sheet, the first dielectric material 639 may be seen, separating access device and storage node regions in the first direction (D1) 609, and having the horizontal opening filled with the second dielectric material 633 and the first dielectric material 639.

FIG. 6D illustrates a cross sectional view, taken along cut-line D-D′ in FIG. 6A, showing another view of the semiconductor structure at this particular point in one example semiconductor fabrication process for forming bifurcated access line contacts in vertical three dimensional (3D) memory, in accordance with a number of embodiments of the present disclosure. The cross sectional view shown in FIG. 6D is illustrated, right to left in the plane of the drawing sheet, extending in the first direction (D1) 609 along an axis of the repeating iterations of alternating layers of first dielectric material 639 and single crystalline silicon (Si) material 632 wrapped with a gate dielectric material 642. The gate dielectric material 642 may be conformally deposited fully around every surface of the single crystalline silicon (Si) material 632, to form gate all around (GAA) gate structures, at the channels of the access device regions. The first conductive material 677 may fill the spaces adjacent the bridged single crystalline silicon (Si) material 632. The single crystalline silicon (Si) material 632 may be surrounded by the first conductive material 677 formed on the gate dielectric material 642. The first conductive material 677 may be conformally deposited fully around every surface of the single crystalline silicon (Si) material 632, to form gate all around (GAA) gate structures, at the channels of the access device regions. In FIG. 6D, the first conductive material, 677 is shown filling in the space in the second horizontal openings left by the etched second dielectric material 633.

FIGS. 7A to 7B illustrate an example method, at another stage of a semiconductor fabrication process, for forming vertical three-dimensional (3D) memory in accordance with a number of embodiments of the present disclosure.

A first conductive material 777 was deposited on the gate dielectric material and formed around the single crystalline silicon (Si) material 732, recessed back, to form gate all around (GAA) structure opposing channel regions of the single crystalline silicon (Si) material 732. The first conductive material 777, formed on the gate dielectric material 742, may be recessed and etched away from the vertical opening 770. In some embodiments, the first conductive material 777 may be etched using an atomic layer etching (ALE) process. In some embodiments, the first conductive material 777 may be etched using an isotropic etch process. The first conductive material 777 may be selectively etched leaving the oxide material 742 covering the epitaxially grown, single crystalline silicon (Si) material 732 and the first dielectric material 739 intact. The first conductive material 777 may be selectively etched in the second direction, in the continuous horizontal openings, a third distance (DIST 3) in a range of twenty (20) to fifty (50) nanometers (nm) back from the first vertical opening 770. The first conductive material 777 may be selectively etched around the single crystalline silicon (Si) material 732 back into the continuous horizontal openings extending in the first horizontal direction.

FIG. 7A illustrates an example method, at another stage of a semiconductor fabrication process, for forming bifurcated access line contacts in vertical three dimensional (3D) memory, in accordance with a number of embodiments of the present disclosure. The cross sectional view shown in FIG. 7A is illustrated extending in the second horizontal direction (D2) 705, left and right along the plane of the drawing sheet, along an axis of the repeating iterations of alternating layers of the silicon germanium (SiGe) material 730 and the single crystalline silicon (Si) material 732.

FIG. 7B illustrates an example method, at another stage of a semiconductor fabrication process, for forming bifurcated access line contacts in vertical three dimensional (3D) memory, in accordance with a number of embodiments of the present disclosure. The cross sectional view shown in FIG. 7B is illustrated extending in the second direction (D2) 705, left and right in the plane of the drawing sheet, along an axis of the repeating iterations of alternating layers of the etched first conductive material 777 and single crystalline silicon (Si) material 732.

In FIG. 7B, first dielectric material 739 is shown spaced along a first horizontal direction (D1) 709 extending into and out from the plane of the drawings sheet, for a three dimensional (3D) array of vertically oriented memory cells. At the left end of the drawing sheet is shown the first conductive material 777 formed on the gate dielectric material 742, was etched away from the vertical opening 770. The first conductive material 777, formed on the gate dielectric material 742, is also recessed back in the continuous horizontal openings extending in the first horizontal direction 709. The first conductive material 777 may be selectively etched leaving the oxide material 742 covering the single crystalline silicon (Si) material 732 intact. In some embodiments, the first conductive material 777 may be etched using an atomic layer etching (ALE) process. In some embodiments, the first conductive material 777 may be etched using an isotropic etch process.

FIG. 8 illustrates an example method, at another stage of a semiconductor fabrication process, for forming vertical three-dimensional (3D) memory in accordance with a number of embodiments of the present disclosure. FIG. 8 is a cross sectional view showing another view of the semiconductor structure at a particular time in the semiconductor fabrication process. In FIG. 8, digit line 841 is formed of a conductive material. In FIG. 8, one or more etchant processes can be utilized to form the storage node region 850. The storage node region 850 can include storage nodes (e.g., horizontally oriented capacitor cells) having the first electrodes 861, e.g., bottom electrodes to be coupled to source/drain regions of horizontal access devices, and second electrodes 856, e.g., top electrodes to be coupled to a common electrode plane such as a ground plane. In FIG. 8, a neighboring, horizontal access line 877 is illustrated adjacent the second dielectric material 833, with a portion of the first conductive material 877 located above the Si material 832, and a portion of the first conductive material 877 located below the Si material 832 extending in a direction inward and outward from the plane and orientation of the drawing sheet.

Additionally, as illustrated in FIG. 8, the ILD material 867 can be removed from the vertical opening 870 and up to a vertical sidewall of the vertical opening 870, resulting in a vertical stack in the vertical opening 870 of alternating ILD material 867, dielectric material 839, ILD material 867, gate dielectric material 842, Si material 832, dielectric material 842, ILD fill material 867, etc.

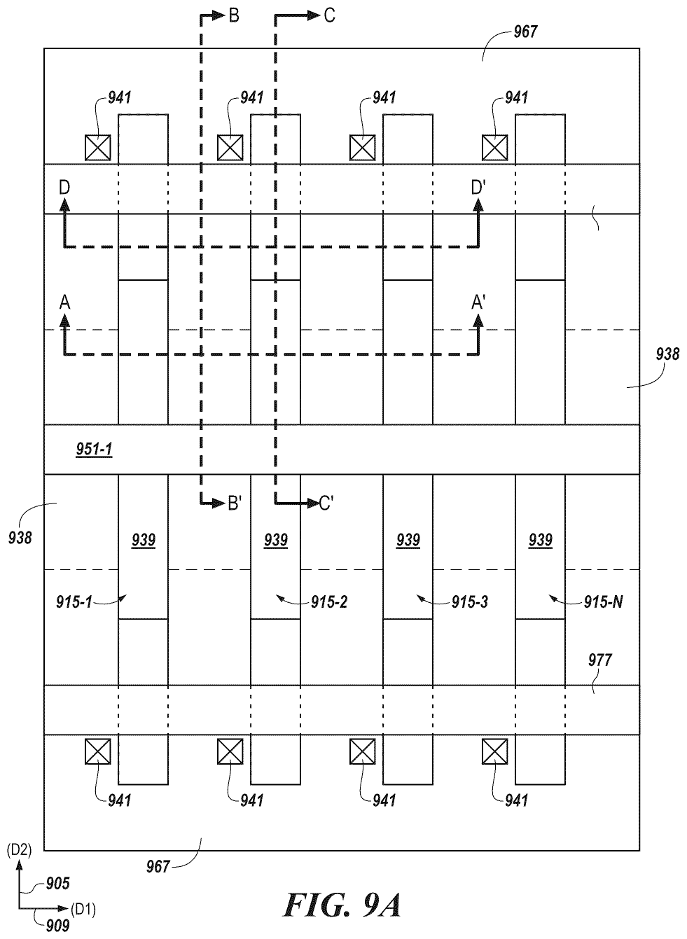

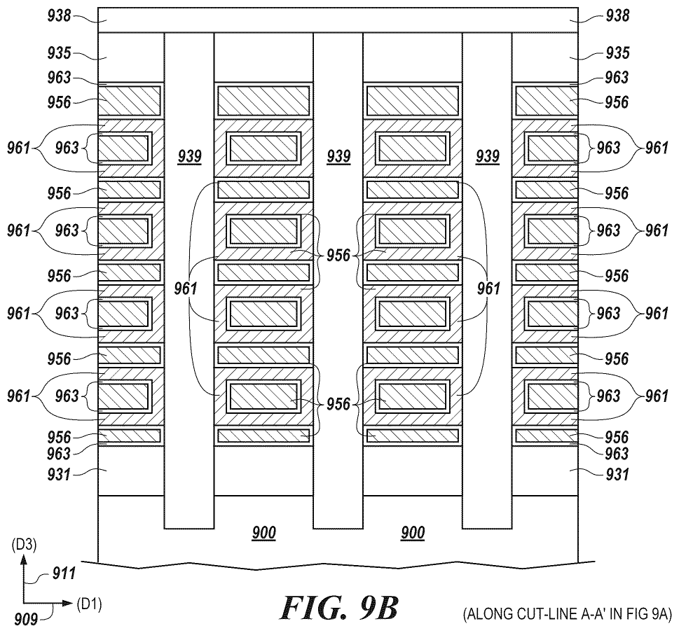

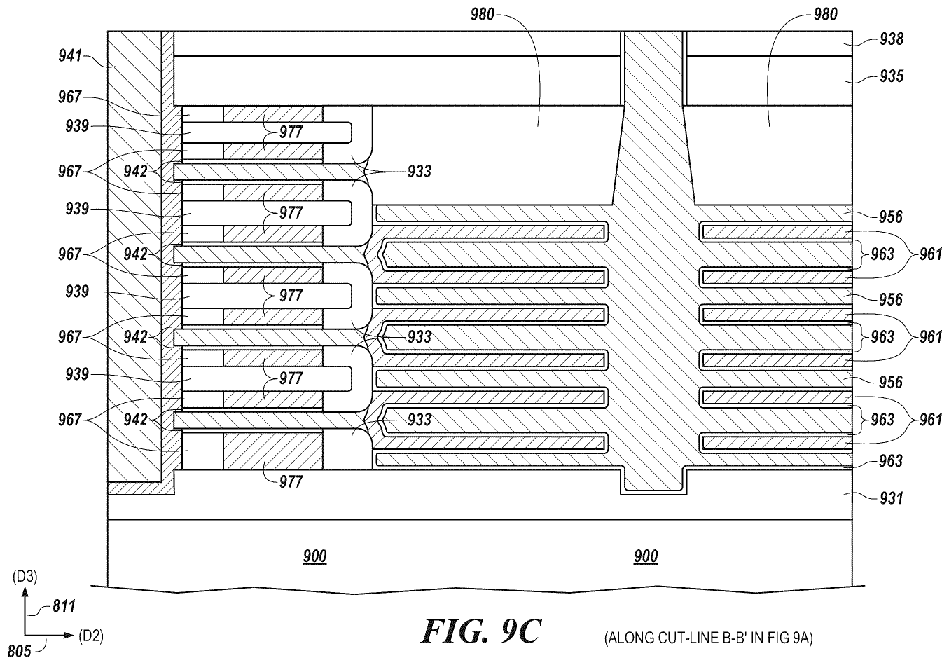

FIGS. 9A to 9C illustrate an example method, at another stage of a semiconductor fabrication process, for forming vertical three-dimensional (3D) memory in accordance with a number of embodiments of the present disclosure.

As illustrated in FIG. 9A, a vertical opening 951 can be formed in a storage node region 950 through the vertical stack and extending predominantly in the first horizontal direction (D1) 909. The vertical opening 951 can be formed from one or more etchant processes to expose sidewalls in the repeating iterations of alternating layers of alternating silicon germanium (SiGe), 930-1, 930-2, . . . , 930-N layers and epitaxially grown, single crystalline silicon (Si) material, 432-1, 432-2, . . . , 432-N layers, shown in FIG. 4A in the vertical stack in order to form storage nodes.

FIG. 9B is a cross sectional view, taken along cut-line A-A′ in FIG. 9B, showing another view of the semiconductor structure at a particular time in the semiconductor fabrication process. The cross-sectional view shown in FIG. 9B is away from the plurality of separate, horizontal access lines 977, and shows repeating iterations of alternating layers of second electrodes 956 separated by horizontally oriented capacitor cells having first electrodes 961, e.g., bottom cell contact electrodes, cell dielectric material 963, and top, common node electrodes, on a semiconductor substrate 900 to form the vertical stack. In the example embodiment of FIG. 9C, the first electrodes 961, e.g., bottom electrodes to be coupled to source/drain regions of horizontal access devices, and second electrodes 956 are illustrated separated by a cell dielectric material 963 extending into and out of the plane of the drawing sheet in second direction (D2) and along an axis of orientation of the horizontal access devices and horizontal storage nodes of the arrays of vertically stacked memory cells of the 3D memory. In FIG. 9C, the first dielectric material 939 is shown separating the space between neighboring horizontally oriented access devices and horizontally oriented storage nodes.

FIG. 9C is a cross sectional view, taken along cut-line B-B′ in FIG. 9A, showing another view of the semiconductor structure at a particular time in the semiconductor fabrication process. In FIG. 9C, the one or more etchant processes can be utilized to form the storage node region 950. The storage node region 950 can include storage nodes (e.g., horizontally oriented capacitor cells) having the first electrodes 961, e.g., bottom electrodes to be coupled to source/drain regions of horizontal access devices, and second electrodes 956, e.g., top electrodes to be coupled to a common electrode plane such as a ground plane. The storage nodes are shown formed in a third horizontal opening 979, extending in second direction (D2) 905, left and right in the plane of the drawing sheet, a third distance from the vertical opening formed in the vertical stack and along an axis of orientation of the horizontal access devices and horizontal storage nodes of the arrays of vertically stacked memory cells of the three-dimensional (3D) memory. In FIG. 9B, a neighboring, horizontal access line 977 is illustrated adjacent the second dielectric material 933, with a portion of the first conductive material 977 located above the Si material 932, and a portion of the first conductive material 977 located below the Si material 932 extending in a direction inward and outward from the plane and orientation of the drawing sheet.

Additionally, as illustrated in FIG. 9C, the ILD material 967 can be removed from the vertical opening 970 and up to a vertical sidewall of the vertical opening 970, resulting in a vertical stack in the vertical opening 970 of alternating ILD material 967, dielectric material 939, ILD material 967, gate dielectric material 942, Si material 932, dielectric material 942, ILD fill material 967, etc.

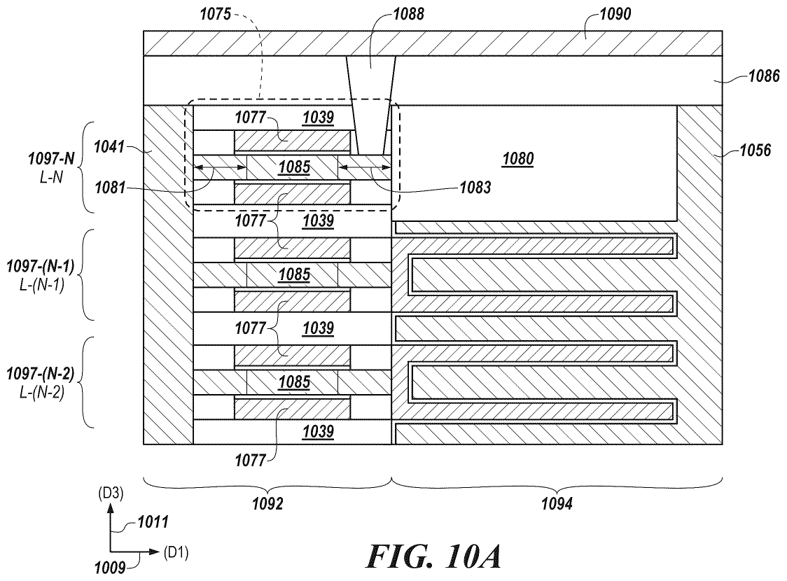

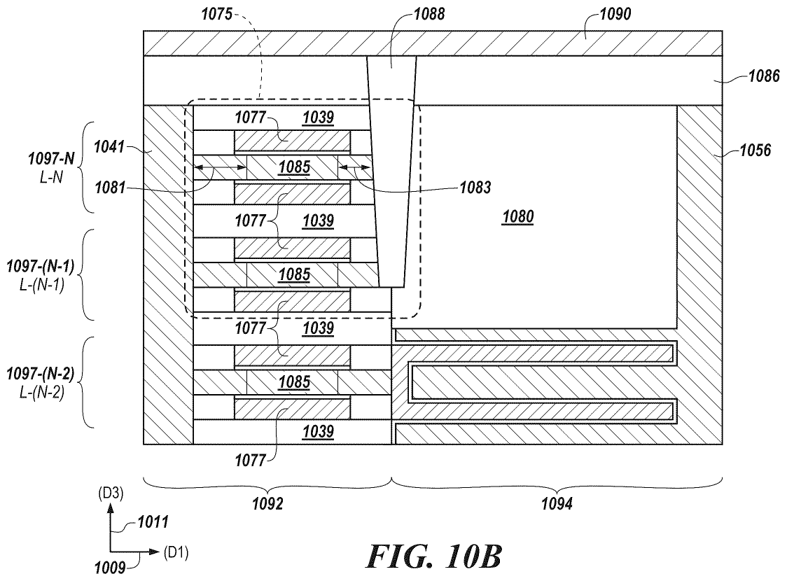

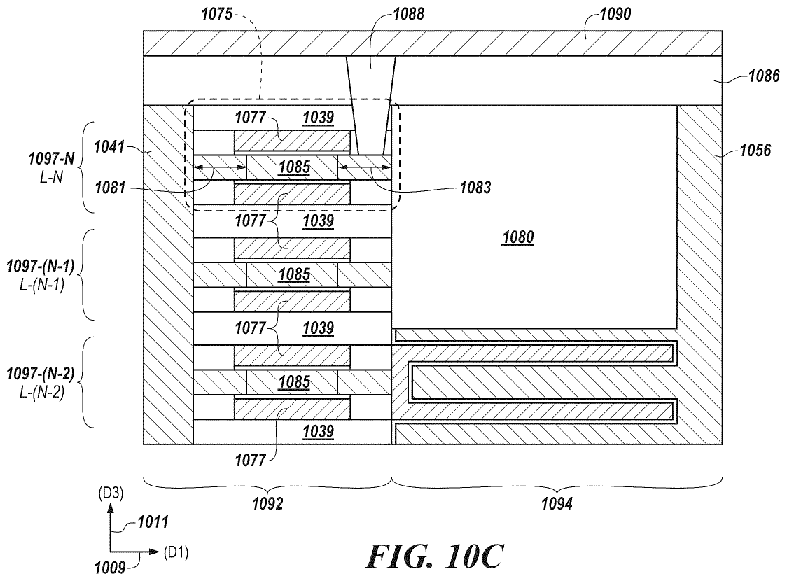

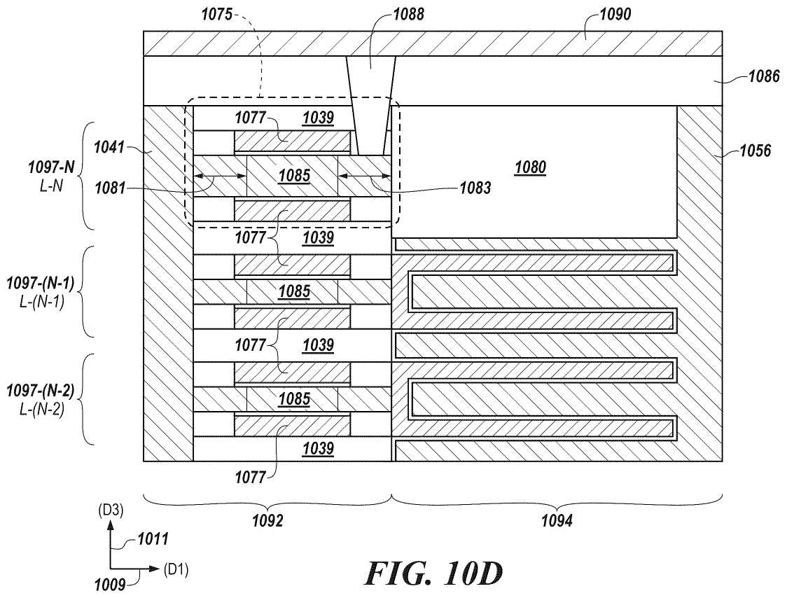

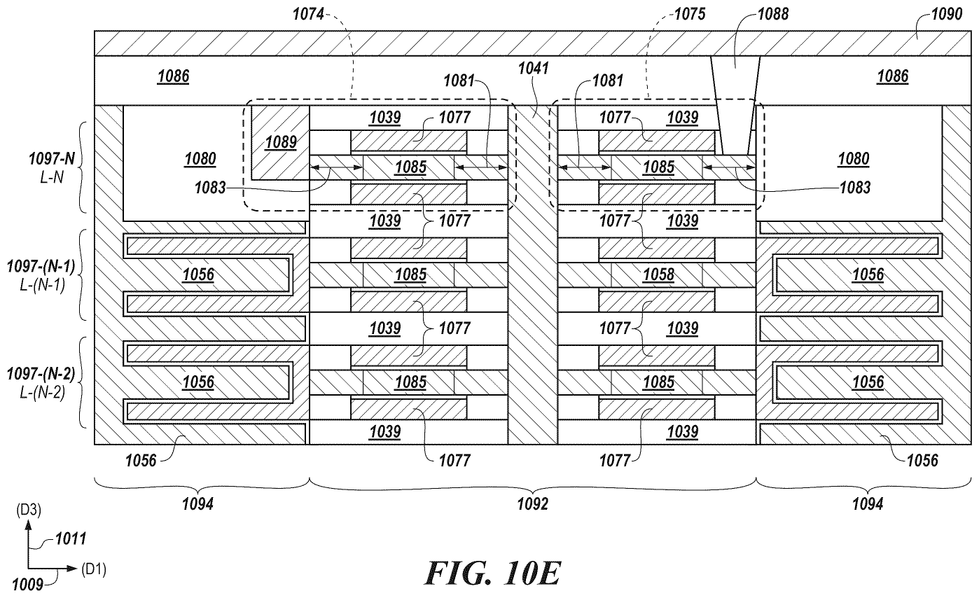

FIGS. 10A to 10E are block diagrams of multiplexer devices 1075 formed with an array of vertically stacked memory cells in vertical three-dimensional (3D) memory in accordance with a number of embodiments of the present disclosure. As described herein in earlier drawings and as shown in FIG. 10A, the vertical 3D memory 1001 can be formed in multiple levels, L1, L2, . . . , LN. As shown in the example embodiment of FIG. 10A the multiplexer device 1075 can be formed in an upper level of the array of vertically stacked memory cells. In some embodiments, shown in further Figures, multiple multiplexer devices can be formed, and function collectively, in multiple upper levels. For example, multiple multiplexer devices can be formed in parallel in an uppermost level L-N 1097-N, a second uppermost level L-(N−1) 1097-(N−1), a third uppermost layer 1097-(N−2), etc.

As shown in the example embodiment of FIG. 10A, the multiplexer device 1075 can be formed in an access device region 1092 when formed with the array of vertically stacked memory cells in vertical 3D memory 1001 by replacing memory cell access devices in an uppermost level L-N 1097-N, the second uppermost level L-(N−1) 1097-(N−1), and/or a third uppermost level L-(N−2) 1097-(N−2) of the array of vertically stacked memory cells, etc. The multiplexer device 1075 can be coupled to a global digit line 1090 that can be operated to access memory cells in a column of the array of vertically stacked memory cells in vertical 3D memory that includes the multiplexer device 1075.

The multiplexer device 1075 can include a channel region 1085, a first source/drain region 1081, a second source/drain region 1083, access lines forming gates, 1077, and separated from the channel regions by a gate dielectric. In the example embodiment of FIG. 10A, the access lines 1077 are shown formed above and below the channel region 1085 as gate all around structures (GAA) in the multiplexer device 1075, similar to the memory cell access devices in the vertical 3D memory 1001. In some embodiments, the access lines forming gates 1077 of the horizontally oriented multiplexer device 1075 can be formed extending above and below portions of the first and second source drain regions, 1081 and 1083, with the gate dielectric also extending and separating the extended access lines 1077 from the first and second source/drain regions. In some embodiments, the first and second source/drain regions, 1081 and 1083, of the multiplexer device 1075 can have increased doping concentrations compared to the first source/drain regions of the horizontally oriented access devices of the memory cells in the array of vertically stacked memory cells. The increased doping concentrations can cause the multiplexer device to have wider source/drain regions and a shorter channel length (cL) in the channel regions than the access devices of the memory cells in the array of vertically stacked memory cells. Thus, the multiplexer device 1075 can have improved on current (Ion) performance when compared to access devices of the memory cells in the array of vertically stacked memory cells and/or multiplexer devices that are located outside of the array of vertically stacked memory cells.

The multiplexer device 1075 can include a digit line contact 1088 that electrically couples the second source/drain region 1083 to a global digit line 1090. The global digit line 1090 can be electrically isolated from the array of vertically stacked memory cells including multiplexer device 1075 by an isolation region 1086 that is formed on the array of vertically stacked memory cells. The digit line contact 1088 can be formed in a vertical opening formed through the isolation region 1086 to reach the second source/drain region 1083 of the multiplexer device 1075.

In FIG. 10A, multiplexer device 1075 can be formed in the uppermost level L-N 1097-N of the array of vertically stacked memory cells. The multiplexer device 1075 can be formed horizontally adjacent to an isolation region 1080. As described above, herein, isolation region 1080 can be formed in a storage node region 1094 of the array of vertically stacked memory cells. According to embodiments, isolation region 1080 can be formed from an insulator material that can block the formation of a storage node in the uppermost level of the array of vertically stacked memory cells during the storage node fabrication process. The isolation region 1080 can be formed so that the multiplexer device 1075 is not horizontally adjacent to a storage node, but rather horizontally adjacent to an insulator in isolation region 1080 allowing the multiplexer device 1075 to act as an access device that can be coupled to a global digit line 1090 via digit line contact 1088 and operated to access memory cells in a column of the array of vertically stacked memory cells that includes the multiplexer device. The levels of the array of vertically stacked memory cells below multiplexer device 1075 can include memory cells on each layer of the array of vertically stacked memory cells.

FIG. 10B is a block diagram of multiplexer devices in an array of vertically stacked memory cells in accordance with a number of embodiments of the present disclosure. In FIG. 10B, multiplexer device 1075-1 can be formed in the uppermost level L-N 1097-N of the array of vertically stacked memory cells and multiplexer device 1075-2 can be formed in the level directly below the uppermost level L-(N−1) 1097-(N−1) of the array of vertically stacked memory cells. The multiplexer devices 1075-1 and 1075-2 can be formed horizontally adjacent to an isolation region 1080. Isolation region 1080 can be formed in a storage node region 1094 of the array of vertically stacked memory cells. Isolation region 1080 can be formed in the uppermost level of the array of vertically stacked memory cells and the level directly below the uppermost level. Isolation region 1080 can be formed from an insulator material that can block the formation of a storage node in the uppermost level of the array of vertically stacked memory cells and the level directly below the uppermost level during the storage node fabrication process. The isolation region 1080 can be formed so that the multiplexer access devices 1075-1 and 1075-2 are not horizontally adjacent to a storage node, but rather horizontally adjacent to an insulator in isolation region 1080 allowing the multiplexer devices 1075-1 and 1075-2 to act as access devices that can be coupled to a global digit line 1090 via digit line contact 1088 and operated to access memory cells in a column of the array of vertically stacked memory cells that includes the multiplexer device. The levels of the array of vertically stacked memory cells below multiplexer devices 1075-1 and 1075-2 can include memory cells on each level of the array of vertically stacked memory cells.

FIG. 10C is a block diagram of a multiplexer device in an array of vertically stacked memory cells in accordance with a number of embodiments of the present disclosure. In FIG. 10C, multiplexer device 1075 can be formed in the uppermost level L-N 1097-N of the array of vertically stacked memory cells. The multiplexer device 1075 can be formed horizontally adjacent to an isolation region 1080. Isolation region 1080 can be formed in storage node region 1094 of the array of vertically stacked memory cells. Isolation region 1080 can be formed in the uppermost level of the array of vertically stacked memory cells and the level directly below the uppermost level. Isolation region 1080 can be formed from an insulator material that can block the formation of a storage node in the uppermost level of the array of vertically stacked memory cells and the layer directly below the uppermost layer during the storage node fabrication process. The isolation region 1080 can be formed so that the multiplexer device 1075 is not horizontally adjacent to a storage node, but rather horizontally adjacent to an insulator in isolation region 1080 allowing multiplexer device 1075 to act as an access device that can be coupled to global digit line 1090 via digit line contact 1088 and operated to access memory cells in a column of the array of vertically stacked memory cells that includes the multiplexer device. The levels of the array of vertically stacked memory cells below multiplexer device 1075 and isolation region 1080 can include memory cells on each level of the array of vertically stacked memory cells. The level below the multiplexer device 1075 can include an access device that is a dummy (e.g., non-functional) to allow a buffer between the multiplexer devices 1075 and the access devices of the memory cells in the array. The buffer can prevent operation of the multiplexer device 1075 from affecting operations on the memory cells in the array.

FIG. 10D is a block diagram of a multiplexer device 1075 in an array of vertically stacked memory cells in accordance with a number of embodiments of the present disclosure. In FIG. 10D, multiplexer device 1075 can be formed in the uppermost level L-N 1097-N of the array of vertically stacked memory cells. The multiplexer device 1075 can be formed horizontally adjacent to an isolation region 1080. Isolation region 1080 can be formed in storage node region 1094 of the array of vertically stacked memory cells. Isolation region 1080 can be formed from an insulator material that can block the formation of a storage node in the uppermost level L-N 1097-N of the array of vertically stacked memory cells during the storage node fabrication process. The isolation region 1080 can be formed so that the multiplexer device 1075 is not horizontally adjacent to a storage node, but rather horizontally adjacent to an insulator in isolation region 1080 allowing the multiplexer device 1075 to act as an access device that can be coupled to a global digit line 1090 via digit line contact 1088 and operated to access memory cells in a column of the array of vertically stacked memory cells that includes the multiplexer device. The levels of the array of vertically stacked memory cells below multiplexer device 1075 can include memory cells on each level of the array of vertically stacked memory cells. The channel region 1085 and/or the first and second source/drain regions 1081, 1083 of the multiplexer device 1075 can be formed with a thickness that is greater than the channel regions and/or the first and second source/drain regions of access devices of memory cells in the array of vertically stacked memory cells. The increased thickness of the channel regions 1085 and/or first and second source/drain regions 1081, 1083 can improve on/off current (Ion/off) performance of the multiplexer device 1075 when compared to access devices of the memory cells in the array of vertically stacked memory cells and/or multiplexer devices that are located outside of the array of vertically stacked memory cells.

FIG. 10E is a block diagram of a multiplexer device and a bleeder access device 1079 in an array of vertically stacked memory cells in accordance with a number of embodiments of the present disclosure. In FIG. 10E, multiplexer device 1075 and bleeder access device 1079 can be formed in the uppermost level L-N 1097-N of the array of vertically stacked memory cells. The multiplexer device 1075 can be formed horizontally adjacent to an isolation region 1080. Isolation region 1080 can be formed in a storage node region of the array of vertically stacked memory cells. Isolation region 1080 can be formed from an insulator material that can block the formation of a storage node in the uppermost level of the array of vertically stacked memory cells during the storage node fabrication process. The isolation region 1080 can be formed so that the multiplexer device 1075 is not horizontally adjacent to a storage node, but rather horizontally adjacent to an insulator in isolation region 1080 allowing the multiplexer device 1075 to act as an access device that can be coupled to a global digit line 1090 via digit line contact 1088 and operated to access memory cells in a column of the array of vertically stacked memory cells that includes the multiplexer device. The levels of the array of vertically stacked memory cells below multiplexer device 1075 can include memory cells on each level of the array of vertically stacked memory cells.

The bleeder access device 1079 can be formed horizontally adjacent to an isolation region 1080. Isolation region 1080 can be formed in a storage node region of the array of vertically stacked memory cells. Isolation region 1080 can be formed from an insulator material that can block the formation of a storage node in the uppermost level of the array of vertically stacked memory cells during the storage node fabrication process. The levels of the array of vertically stacked memory cells below bleeder access device 1079 can include memory cells on each level of the array of vertically stacked memory cells. The isolation region 1080 can be formed so that the bleeder access device 1079 is not horizontally adjacent to a storage node, but rather horizontally adjacent to an insulator in isolation region 1080 allowing the bleeder access device 1079 to provide a bias voltage on the memory cells on each level of the array of vertically stacked memory cells, including memory cells in a column that includes the multiplexer device 1075 share digit line 1041. The memory cells below the bleeder access device 1079 and the multiplexer device 1075 share digit line 1041. The bias voltage can be provided via conductive line 1089, that is parallel to the access lines 1077, when the bleeder access device 1079 is turned on via a signal on access lines 1077.

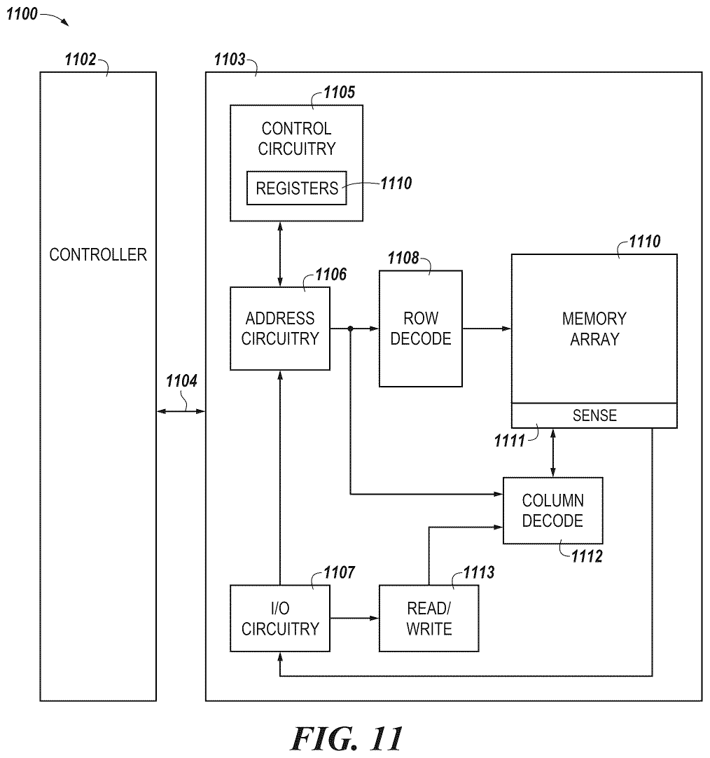

FIG. 11 is a block diagram of an apparatus in the form of a computing system 1100 including a memory device 1103 in accordance with a number of embodiments of the present disclosure. As used herein, a memory device 1103, a memory array 1110, and/or a host 1102, for example, might also be separately considered an “apparatus.” According to embodiments, memory device 1102 may comprise at least one memory array 1110 with a memory cell formed having a digit line and body contact, according to the embodiments described herein.

In this example, system 1100 includes a host 1102 coupled to memory device 1103 via an interface 1104. The computing system 1100 can be a personal laptop computer, a desktop computer, a digital camera, a mobile telephone, a memory card reader, or an Internet-of-Things (IoT) enabled device, among various other types of systems. Host 1102 can include a number of processing resources (e.g., one or more processors, microprocessors, or some other type of controlling circuitry) capable of accessing memory 1103. System 1100 can include separate integrated circuits, or both the host 1102 and the memory device 1103 can be on the same integrated circuit. For example, the host 1102 may be a system controller of a memory system comprising multiple memory devices 1103, with the system controller 1105 providing access to the respective memory devices 1103 by another processing resource such as a central processing unit (CPU).

In the example shown in FIG. 11, the host 1102 is responsible for executing an operating system (OS) and/or various applications (e.g., processes) that can be loaded thereto (e.g., from memory device 1103 via controller 1105). The OS and/or various applications can be loaded from memory device 1103 by providing access commands from the host 1102 to the memory device 1103 to access the data comprising the OS and/or the various applications. The host 1102 can also access data utilized by the OS and/or various applications by providing access commands to the memory device 1103 to retrieve said data utilized in the execution of the OS and/or the various applications.

For clarity, the system 1100 has been simplified to focus on features with particular relevance to the present disclosure. The memory array 1110 can be a DRAM array comprising at least one memory cell having a digit line and body contact formed according to the techniques described herein. For example, memory array 1110 can be an unshielded DL 4F2 array such as a 3D-DRAM memory array. The array 1110 can comprise memory cells arranged in rows coupled by word lines (which may be referred to herein as access lines or select lines) and columns coupled by digit lines (which may be referred to herein as sense lines or data lines). Although a single array 1110 is shown in FIG. 11, embodiments are not so limited. For instance, memory device 1103 may include a number of arrays 1110 (e.g., a number of banks of DRAM cells).

The memory device 1103 includes address circuitry 1106 to latch address signals provided over an interface 1104. The interface can include, for example, a physical interface employing a suitable protocol (e.g., a data bus, an address bus, and a command bus, or a combined data/address/command bus). Such protocol may be custom or proprietary, or the interface 1104 may employ a standardized protocol, such as Peripheral Component Interconnect Express (PCIe), Gen-Z, CCIX, or the like. Address signals are received and decoded by row decoder 1108 and a column decoder 1112 to access the memory array 1110. Data can be read from memory array 1110 by sensing voltage and/or current changes on the sense lines using sensing circuitry 1111. The sensing circuitry 1111 can comprise, for example, sense amplifiers that can read and latch a page (e.g., row) of data from the memory array 1110. The I/O circuitry 1107 can be used for bi-directional data communication with the host 1102 over the interface 1104. The read/write circuitry 1113 is used to write data to the memory array 1110 or read data from the memory array 1110. As an example, circuitry 1113 can comprise various drivers, latch circuitry, etc.

Control circuitry 1105 decodes signals provided by host 1102. The signals can be commands provided by the host 1102. These signals can include chip enable signals, write enable signals, and address latch signals that are used to control operations performed on the memory array 1110, including data read operations, data write operations, and data erase operations. In various embodiments, the control circuitry 1105 is responsible for executing instructions from the host 1102. The control circuitry 1105 can comprise a state machine, a sequencer, and/or some other type of control circuitry, which may be implemented in the form of hardware, firmware, or software, or any combination of the three. In some examples, the host 1102 can be a controller external to the memory device 1103. For example, the host 1102 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact with the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A method of forming a three dimensional (3D) memory device, comprising:
forming a vertical stack having an array of memory cells including horizontally oriented access devices and horizontally oriented storage nodes;
forming a first isolation region within an uppermost level of the vertical stack vertically above a given one of the horizontally oriented storage nodes;
forming doped first silicon regions within the uppermost level of the vertical stack vertically above a given one of the horizontally oriented access devices by doping first silicon regions within the vertical stack through a plurality of spaced first openings; and
forming a multiplexer device, adjacent the first isolation region within the uppermost level of the vertical stack, the multiplexer device having the doped first silicon regions as first and second source/drain regions.

2. The method of claim 1, further including forming first vertical digit lines connected to the first source/drain regions of the access devices and a first one of the doped first regions and forming a digit line contact to a second one of the doped first regions.

3. The method of claim 1, further including forming a second isolation layer over the first isolation layer and the access device region and forming the digit line contact through the second isolation layer that contacts the second source/drain region of the multiplexer device.

4. The method of claim 3, further including forming a second digit line on the second isolation layer and the digit line contact.

5. The method of claim 4, wherein the first digit line is a local digit line of the vertical stack having the array of memory cells, and the second digit line is a global digit line connected to a plurality of vertically stacked arrays of memory cells.

6. The method of claim 1, wherein the multiplexer device is configured as a multiplexer for a number of memory cells coupled to the first digit line in the vertical stack having the array of memory cells.

7. The method of claim 1, further including forming the multiplexer device to have a shorter channel length than channel lengths of horizontally oriented access devices in the vertical stack having the array of memory cells.

8. The method of claim 1, further including forming the first and the second source/drain regions of the multiplexer device to have source/drain lengths greater than source/drain lengths of the horizontally oriented access devices in the vertical stack having the array of memory cells.

9. The method of claim 1, further including forming the first and the second source/drain regions of the multiplexer device to have source/drain doping concentrations greater than source/drain doping concentrations of the horizontally oriented access devices in the vertical stack having the array of memory cells.

10. A method of forming a three dimensional (3D) memory device, comprising:
forming a first isolation region in a storage node region of an array of vertically stacked memory cells, the array having horizontally oriented access devices and storage nodes;
forming a multiplexer device in an access device region of the array of vertically stacked memory cells, wherein the multiplexer device is horizontally adjacent to the first isolation region;
forming a digit line contact that is coupled to a first source/drain region of the multiplexer device; and
forming a first digit line that is coupled to a second source/drain region of the multiplexer device.

11. The method of claim 10, further including electrically coupling a second digit line to the first source/drain region of the multiplexer device via the digit line contact.

12. The method of claim 10, further including forming the multiplexer device to have a shorter channel length than channel lengths of horizontally oriented access devices in the array of vertically stacked memory cells.

13. The method of claim 10, further including forming the first source/drain region and the second source/drain region of the multiplexer device to have source/drain lengths greater than source/drain lengths of the horizontally oriented access devices in the array of vertically stacked memory cells.

14. The method of claim 10, including forming the isolation region in an uppermost layer of the array of vertically stacked memory cells.

15. The method of claim 10, including forming the isolation region in an uppermost layer of the array of vertically stacked memory cells and in a layer directly below the uppermost layer of the array of vertically stacked memory cells.

16. The method of claim 10, further including forming another multiplexer device in the storage node region of the array of vertically stacked memory cells, wherein the second multiplexer device is horizontally adjacent to the first isolation region in a layer directly below an uppermost layer of the array of vertically stacked memory cells.

17. An apparatus, comprising:
an array of vertically stacked memory cells, the array having horizontally oriented access devices and storage nodes, comprising:
a first isolation region in a storage node region of an array of vertically stacked memory cells, wherein the isolation region is in an uppermost layer of the array of vertically stacked memory cells;
a multiplexer device in the storage node region of the array of vertically stacked memory cells, wherein the multiplexer device is horizontally adjacent to the first isolation region;
a digit line contact coupled to a first source/drain region of the multiplexer device; and
a first digit line coupled to a second source/drain region of the multiplexer device.

18. The apparatus of claim 17, wherein the isolation region is in an uppermost layer of the array of vertically stacked memory cells and in a layer directly below the uppermost layer of the array of vertically stacked memory cells.

19. The apparatus of claim 17, wherein the array of vertically stacked memory cells is further comprising another multiplexer device in the storage node region of the array of vertically stacked memory cells, wherein the second multiplexer device is horizontally adjacent to the first isolation region in a layer directly below an uppermost layer of the array of vertically stacked memory cells.

20. The apparatus of claim 17, wherein a channel region of the multiplexer device has a thickness greater than a thickness of channel regions of the horizontally oriented access devices in the array of vertically stacked memory cells.
